(19) United States
(12) Patent Application Publication
(10) Pub. No.: US 2025/0287589 A1
(43) Pub. Date: Sep. 11, 2025

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventor: Yonggang YANG, Wuhan (CN)

(21) Appl. No.: 18/631,771

(22) Filed: Apr. 10, 2024

Related U.S. Application Data
(63) Continuation of application No. PCT/CN2024/080913, filed on Mar. 11, 2024.

(51) Int. Cl. H10B 43/27

(52) U.S. Cl. CPC H10B 43/27

(57) ABSTRACT

In certain aspects, a memory device includes a semiconductor layer and a stack structure over the semiconductor layer. The stack structure includes alternating first layers and first dielectric layers. The first layers in a first portion of the stack structure include second dielectric layers, and the first layers in a second portion adjacent to the first portion of the stack structure include conductive layers. The memory device further includes a third dielectric layer over the stack structure and a contact structure. The contact structure extends through the third dielectric layer and a part of the first portion of the stack structure to be connected with a first one of the conductive layers. The contact structure includes a first contact segment and a second contact segment that are connected with each other at a first joint region in the third dielectric layer.

### CROSS-REFERENCE TO RELATED APPLICATIONS

This application is a continuation of International Application No. PCT/CN2024/080913, filed on Mar. 11, 2024, entitled “THREE-DIMENSIONAL MEMORY DEVICES AND METHODS FOR FORMING THE SAME,” which is incorporated herein by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, a memory device includes a semiconductor layer and a stack structure over the semiconductor layer. The stack structure includes alternating first layers and first dielectric layers. The first layers in a first portion of the stack structure include second dielectric layers, and the first layers in a second portion adjacent to the first portion of the stack structure include conductive layers. The memory device further includes a third dielectric layer over the stack structure and a contact structure. The contact structure extends through the third dielectric layer and a part of the first portion of the stack structure to be connected with a first one of the conductive layers. The contact structure includes a first contact segment and a second contact segment which are connected with each other at a first joint region in the third dielectric layer.

In some implementations, the first contact segment extends through a first part of the third dielectric layer in a first direction. The second contact segment extends through a second part of the third dielectric layer and the part of the stack structure in the first direction.

In some implementations, a size of the first contact segment is greater than a size of the second contact segment in a second direction perpendicular to the first direction.

In some implementations, the contact structure includes a vertical contact member extending in a first direction and a lateral contact member connecting to the vertical contact member and extending in a second direction. The lateral contact member connects with the first one of the conductive layers.

In some implementations, the first contact segment includes a first part of the vertical contact member. The second contact segment includes a second part of the vertical contact member and the spacer. The first part and the second part of the vertical contact member connect with each other at the first joint region in the third dielectric layer.

In some implementations, the contact structure further includes a filler body surrounded by the vertical contact member. The first contact segment further includes a first part of the filler body, and the second contact segment further includes a second part of the filler body. The first part and the second part of the filler body connect with each other at the first joint region in the third dielectric layer.

In some implementations, the second dielectric layers in the first portion of the stack structure include a first one of the second dielectric layers at a same level as the first one of the conductive layers and a second one of the second dielectric layers at a same level as a second one of the conductive layers. An end surface of the second one of the conductive layers is covered by a first high dielectric constant (high-k) gate dielectric layer, and the second one of the conductive layers connects with the second one of the second dielectric layers via the first high-k gate dielectric layer. The lateral contact member of the contact structure protrudes into the second portion of the stack structure and connects with the first one of the conductive layers.

In some implementations, side surfaces of the first one of the conductive layers are surrounded by second high-k gate dielectric layers. Side surfaces of the second one of the conductive layers are surrounded by third high-k gate dielectric layers.

In some implementations, the lateral contact member and the first one of the conductive layers include different materials.

In some implementations, the lateral contact member and the first one of the conductive layers include Titanium nitride and tungsten, respectively.

In some implementations, the memory device further includes a slit structure including a first slit segment and a second slit segment. The first slit segment extends through a third part of the third dielectric layer. The second slit segment extends through a fourth part of the third dielectric layer, the first portion of the stack structure, and a part of the semiconductor layer. The first slit segment connects with the second slit segment at a second joint region in the third dielectric layer.

In some implementations, a first distance from the slit structure to an end surface of the first one of the conductive layers in the second direction is smaller than a second distance from the slit structure to the end surface of the second one of the conductive layers in the second direction.

In some implementations, a size of the first slit segment is greater than a size of the second slit segment in the second direction.

In another aspect, a method for forming a memory device is disclosed. The method includes forming a stack structure over a semiconductor layer. The stack structure includes alternating first dielectric layers and second dielectric layers. The method also includes forming a third dielectric layer over the stack structure and forming a contact structure extending through the third dielectric layer and a part of the stack structure. The contact structure includes a first contact segment and a second contact segment that are connected with each other at a first joint region in the third dielectric layer.

In some implementations, forming the contact structure includes forming a spacer, forming a vertical contact member extending in a first direction and a lateral contact member extending in a second direction perpendicular to the first direction, and forming a filler body. The vertical contact member connects with the lateral contact member, and at least a part of the vertical contact member is surrounded by the spacer. The filler body is surrounded by the vertical contact member.

In some implementations, prior to forming the contact structure, the method further includes forming a first slit opening extending through the stack structure and a part of the semiconductor layer. The method also includes filling the first slit opening with a preliminary slit structure. Forming the third dielectric layer includes depositing a first dielectric sub-layer over the stack structure to cover the preliminary slit structure. The third dielectric layer includes the first dielectric sub-layer.

In some implementations, forming the contact structure further includes forming a first contact opening extending through the first dielectric sub-layer and the part of the stack structure. Forming the spacer includes depositing a first dielectric material on a sidewall of the first contact opening.

In some implementations, forming the vertical contact member and the lateral contact member includes forming a lateral recess below a bottom of the first contact opening by removing a part of a first one of the second dielectric layers exposed at the bottom of the first contact opening, and filling the first contact opening and the lateral recess with a second dielectric material different from that of the first dielectric layers and the second dielectric layers.

In some implementations, forming the third dielectric layer further includes depositing a second dielectric sub-layer over the first dielectric sub-layer to cover the second dielectric material filled in the first contact opening. The third dielectric layer further includes the second dielectric sub-layer.

In some implementations, the stack structure includes a first portion and a second portion adjacent to the first portion, and the contact structure extends through the third dielectric layer and a part of the first portion of the stack structure. The method further includes performing a gate line replacement process to replace parts of the second dielectric layers in the second portion of the stack structure with conductive layers.

In some implementations, performing the gate line replacement process includes forming a second slit opening to expose the preliminary slit structure, removing the preliminary slit structure to expose the first slit opening through the second slit opening, removing the parts of the second dielectric layers in the second portion of the stack structure through the first slit opening to form a plurality of lateral openings, forming high-k gate dielectric layers on walls of the plurality of lateral openings, filling the plurality of lateral openings with a first conductive material to form the conductive layers such that end surfaces and side surfaces of the conductive layers are surrounded by the high-k gate dielectric layers, respectively, and forming a slit structure to fill the first slit opening and the second slit opening.

In some implementations, the lateral recess filled with the first dielectric material protrudes into the second portion of the stack structure and connects with a first corresponding high-k gate dielectric layer on an end surface of a first one of the conductive layers. A second one of the second dielectric layers in the first portion of the stack structure connects with a second corresponding high-k gate dielectric layer at an end surface of a second one of the conductive layers.

In some implementations, forming the third dielectric layer further includes depositing a third dielectric sub-layer over the second dielectric sub-layer to cover the slit structure formed in the first and second slit openings. The third dielectric layer further includes the third dielectric sub-layer.

In some implementations, forming the vertical contact member and the lateral contact member further includes forming a second contact opening in the third dielectric layer to expose the second dielectric material filled in the first contact opening, removing the second dielectric material through the second contact opening to expose the lateral recess and a sidewall of the spacer, removing the first corresponding high-k gate dielectric layer on the end surface of the first one of the conductive layers to expose the end surface of the first one of the conductive layers, and depositing a second conductive material to fill the lateral recess, on the sidewall of the spacer, and on a sidewall of the second contact opening to form the lateral contact member and the vertical contact member, respectively. A size of the second contact opening is greater than a size of the first contact opening in the second direction.

In some implementations, the lateral contact member of the contact structure protrudes into the second portion of the stack structure and connects with the first one of the conductive layers.

In some implementations, the first joint region comprises a region where the first contact opening connects with the second contact opening in the third dielectric layer.

In some implementations, forming the filler body includes filling a remaining space of the first contact opening and a remaining space of the second contact opening with a third dielectric material.

In some implementations, the slit structure includes a first slit segment filling the first slit opening and a second slit segment filling the second slit opening. The first slit segment connects with the second slit segment at a second joint region in the third dielectric layer. A size of the first slit segment is greater than a size of the second slit segment in the second direction.

In some implementations, a first distance from the slit structure to the end surface of the first one of the conductive layers in the second direction is smaller than a second distance from the slit structure to the end surface of the second one of the conductive layers in the second direction.

In some implementations, the first contact segment includes a first part of the vertical contact member and a first part of the filler body. The second contact segment includes a second part of the vertical contact member, and a second part of the filler body. The first part and the second part of the vertical contact member connect with each other at the first joint region in the third dielectric layer. The first part and the second part of the filler body connect with each other at the first joint region in the third dielectric layer. A size of the first contact segment is greater than a size of the second contact segment in the second direction perpendicular to the first direction.

In still another aspect, a system includes a memory device and a memory controller coupled to the memory device and configured to control an operation of the memory device. The memory device includes a semiconductor layer and a stack structure over the semiconductor layer. The stack structure includes alternating first layers and first dielectric layers. The first layers in a first portion of the stack structure include second dielectric layers, and the first layers in a second portion adjacent to the first portion of the stack structure include conductive layers. The memory device further includes a third dielectric layer over the stack structure and a contact structure. The contact structure extends through the third dielectric layer and a part of the first portion of the stack structure to be connected with a first one of the conductive layers. The contact structure includes a first contact segment and a second contact segment that are connected with each other at a first joint region in the third dielectric layer.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a plan view of a 3D memory device having contact structures, according to some aspects of the present disclosure.

FIG. 2 illustrates cross-sectional side views of a 3D memory device having contact structures, according to some examples of the present disclosure.

FIGS. 3A-3C illustrate some steps in a fabrication process for forming the 3D memory device of FIG. 2, according to some examples of the present disclosure.

FIG. 4 illustrates cross-sectional side views of a 3D memory device having contact structures, according to some aspects of the present disclosure.

FIG. 5A illustrates a cross-sectional side view of a 3D memory device having contact structures, according to some aspects of the present disclosure.

FIG. 5B illustrates an enlarged cross-sectional side view of a 3D memory device having contact structures, according to some aspects of the present disclosure.

FIG. 5C illustrates a slit structure in a 3D memory device, according to some aspects of the present disclosure.

FIGS. 6A-6R illustrate a fabrication process for forming a 3D memory device having contact structures, according to some aspects of the present disclosure.

FIG. 7 is a flowchart of a method for forming a 3D memory device having contact structures, according to some aspects of the present disclosure.

FIG. 8 illustrates a block diagram of an example system having a 3D memory device, according to some aspects of the present disclosure.

FIG. 9A illustrates a diagram of an example memory card having a 3D memory device, according to some aspects of the present disclosure.

FIG. 9B illustrates a diagram of an example solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical contacts are formed) and one or more dielectric layers.

In some implementations, a 3D memory device may include a substrate and a stack structure over the substrate. The stack structure may include a first portion and a second portion adjacent to the first portion. The first portion of the stack structure may include alternating first dielectric layers and second dielectric layers, and the second portion of the stack structure may include alternating first dielectric layers and conductive layers. A contact structure (e.g., an example word line pick-up structure) may extend through a part of the first portion of the stack structure and connect with a first one of the conductive layers in the second portion. In some implementations, the contact structure may include a spacer, a vertical contact member formed on a sidewall of the spacer, and a lateral contact member in contact with the vertical contact member and connecting to the first one of the conductive layers.

To form the 3D memory device, initially, the stack structure having alternating first dielectric layers and second dielectric layers can be formed (e.g., initially, both the first and second portions of the stack structure include alternating first dielectric layers and second dielectric layers). Subsequently, a gate line replacement process can be performed in the second portion of the stack structure to replace the second dielectric layers in the second portion with conductive layers, respectively. High-k gate dielectric layers may be formed prior to the formation of the conductive layers, such that the conductive layers may be formed surrounded by the high-k gate dielectric layers. Afterwards, the contact structure may be formed in the first portion of the stack structure at least by: (a) forming a contact opening extending through a part of the first portion of the stack structure; (b) forming the spacer on a sidewall of the contact opening; (c) removing part of a first one of the second dielectric layers exposed from the bottom of the contact opening by wet etching to form a lateral recess; (d) forming a lateral contact member by depositing a conductive material through the contact opening to fill the lateral recess, such that the lateral contact member connects with the first one of the conductive layers; and (e) forming the vertical contact member in contact with the lateral contact member by depositing the conductive material on a sidewall of the spacer.

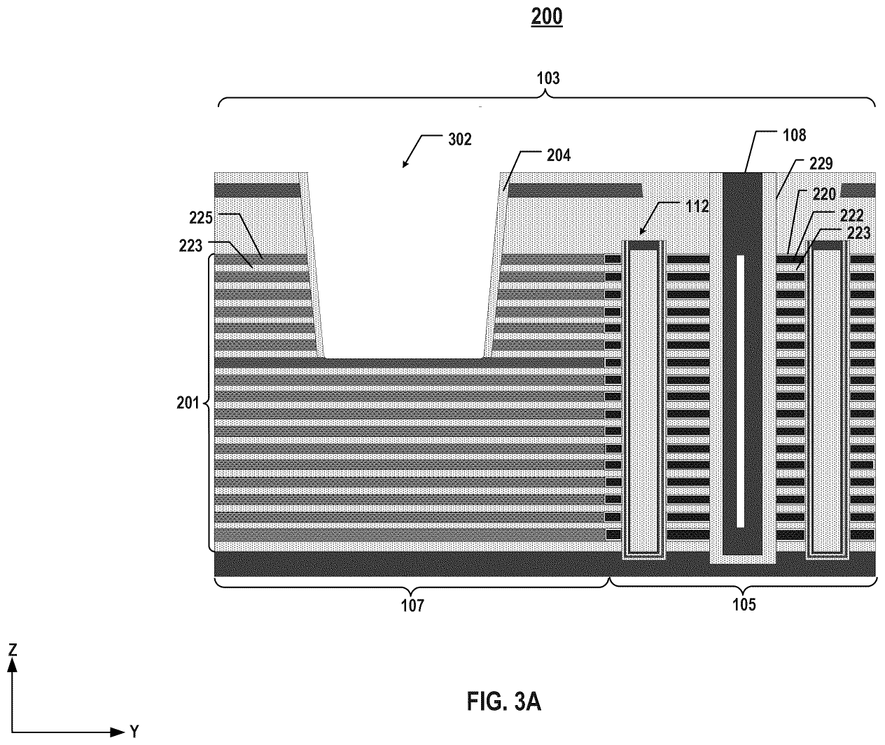

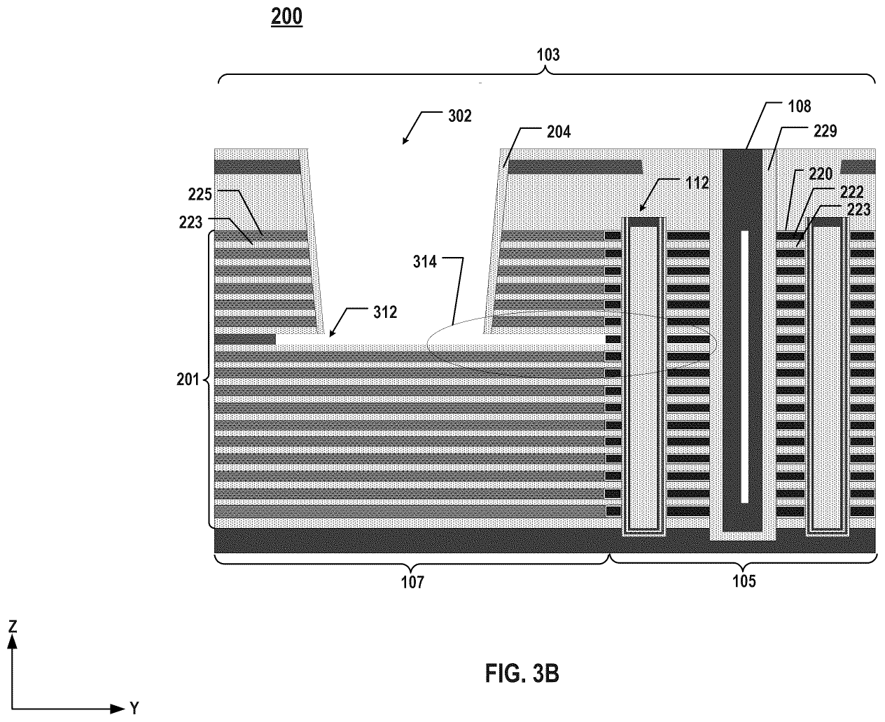

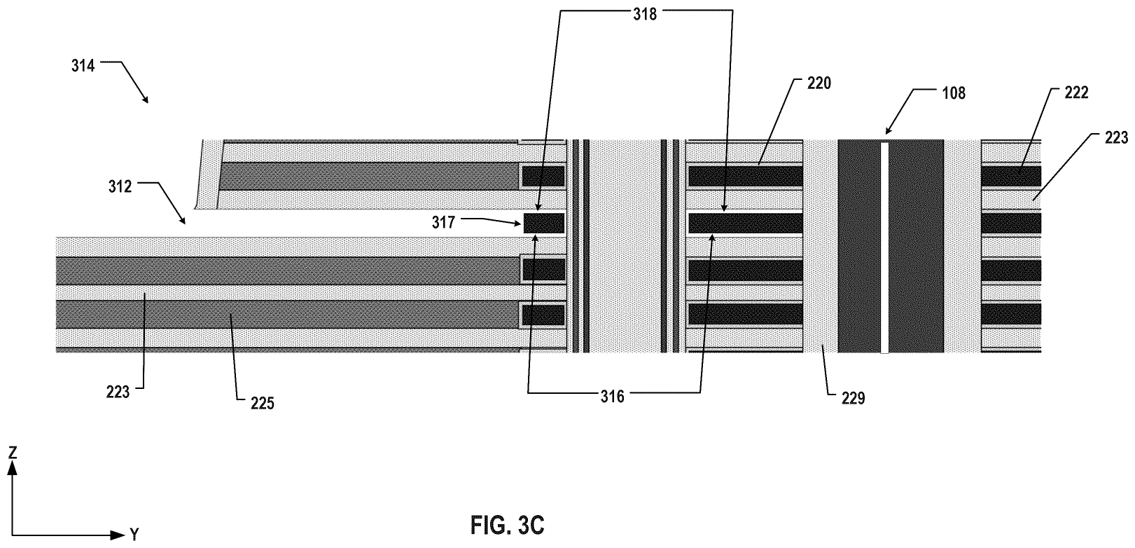

In the above step (c), the part of the first one of the second dielectric layers (including silicon nitride) can be wet etched by applying a wet etchant through the contact opening. However, as described below in more detail with reference to FIGS. 3B-3C, when the part of the first one of the second dielectric layers is etched away by the wet etchant, the high-k gate dielectric layers surrounding the first one of the conductive layers may be over-etched by the wet etchant, resulting in damage in the high-k gate dielectric layers surrounding the first one of the conductive layers. If the high-k gate dielectric layers surrounding the first one of the conductive layers is over etched too much, a spacer of a slit structure in the memory device can also be damaged. It can be difficult to find an appropriate wet etchant or develop a new wet etchant that can be controlled to only etch the first one of the second dielectric layers without over-etching the high-k gate dielectric layers surrounding the first one of the conductive layers. Also, it can be difficult to control an etching rate and/or etching time to remove only the part of the first one of the second dielectric layers that is enough to expose an end surface of the first one of the conductive layers, without over-etching the high-k gate dielectric layers surrounding the first one of the conductive layers.

An example solution to solve the over-etching issue of the high-k gate dielectric layers may include: (1) before forming the lateral contact member, depositing a high-k dielectric material through the lateral recess to repair the damage made to the high-k gate dielectric layers surrounding the first one of the conductive layers; (2) etching back only a high-k gate dielectric layer formed on the end surface of the first one of the conductive layers to expose the end surface of the first one of the conductive layers; and then (3) forming the lateral contact member to connect with the end surface of the first one of the conductive layers. In this case, since (1) additional high-k dielectric material is deposited to repair the damage made to the high-k gate dielectric layers and (2) the high-k gate dielectric layer formed on the end surface of the first one of the conductive layers is etched back again, the manufacturing process of the memory device becomes more complicated, and the cost of the memory device is increased.

To address one or more of the aforementioned issues, the present disclosure introduces a solution that can avoid the over-etching issue of the high-k gate dielectric layers. For example, in the solution disclosed herein, the contact opening and the lateral recess of the contact structure can be formed in the first portion of the stack structure before the gate line replacement process. A dielectric material (such as polysilicon) can be filled in the contact opening and the lateral recess. Then, the gate line replacement process can be performed to form the conductive layers in the second portion of the stack structure. High-k gate dielectric layers may be formed prior to the formation of the conductive layers, such that the conductive layers may be surrounded by the high-k gate dielectric layers. Afterwards, the dielectric material (such as polysilicon) filled in the contact opening and the lateral recess can be removed to expose a high-k gate dielectric layer formed on an end surface of the first one of the conductive layers. In this case, it is relatively easy to perform and control a wet etch to etch away only the dielectric material filled in the lateral recess without damaging the high-k gate dielectric layers surrounding the first one of the conductive layers. Then, the high-k gate dielectric layer on the end surface of the first one of the conductive layers can be removed to expose the end surface of the first one of the conductive layers. Subsequently, the lateral contact member can be formed in the lateral recess in contact with the end surface of the first one of the conductive layers. In the solution disclosed herein, there is no need to develop new wet etchants to avoid the over-etching issue. The etching process can be controlled, and no damage is made to the high-k gate dielectric layers. That is, the over-etching issue of the high-k gate dielectric layers can be avoided. As a result, the manufacture cost of the memory device can be reduced.

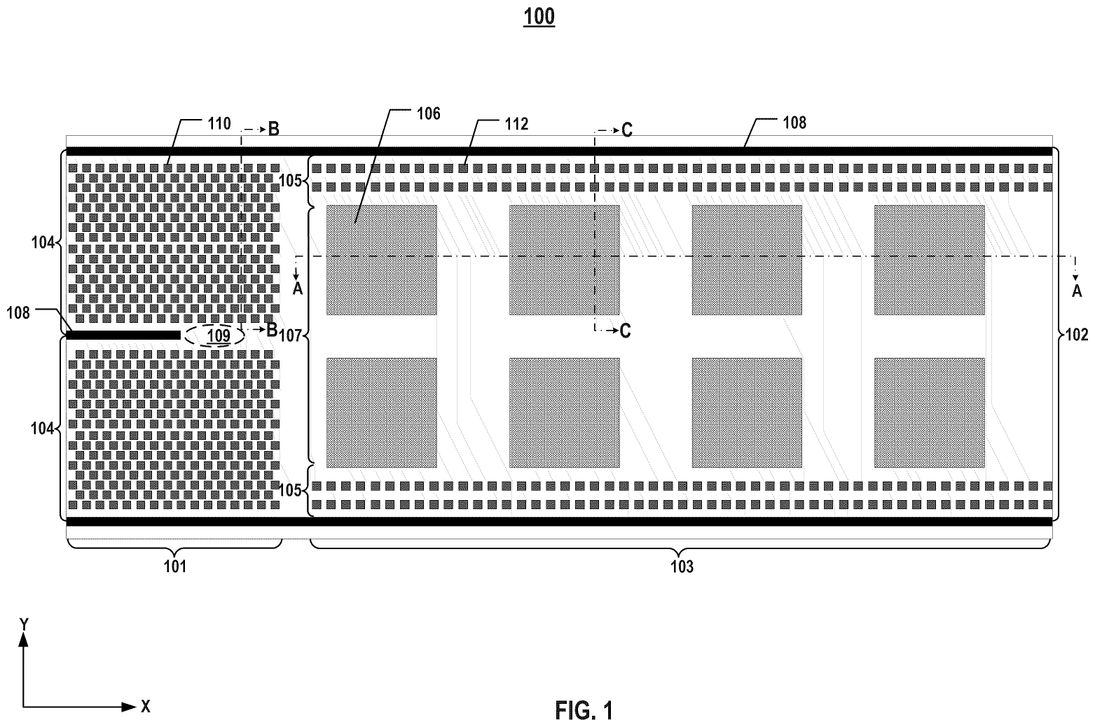

FIG. 1 illustrates a plan view of a 3D memory device 100 having contact structures 106, according to some aspects of the present disclosure. In some implementations, 3D memory device 100 is a NAND Flash memory device in which memory cells are provided in the form of an array of NAND memory strings. It is noted that x and y axes are included in FIG. 1 to illustrate two orthogonal (perpendicular) directions in the wafer plane. The x-direction is the word line direction of 3D memory device 100, and the y-direction is the bit line direction of 3D memory device 100.

As shown in FIG. 1, 3D memory device 100 can include one or more blocks 102 arranged in the y-direction (the bit line direction) separated by parallel slit structures 108, such as gate line slits (GLSs). In some implementations in which 3D memory device 100 is a NAND Flash memory device, each block 102 is the smallest erasable unit of the NAND Flash memory device. Each block 102 can further include multiple fingers 104 in the y-direction separated by some slit structures 108 with “H” cuts 109.

As shown in FIG. 1, 3D memory device 100 can be divided into at least a core array region 101 in which an array of channel structures 110 are formed, as well as a word line pick-up region 103 in which contact structures 106 are formed. Core array region 101 and word line pick-up region 103 are arranged in the x-direction (the word line direction), according to some implementations. It is understood that although one core array region 101 and one word line pick-up region 103 are illustrated in FIG. 1, multiple core array regions 101 and/or multiple word line pick-up regions 103 may be included in 3D memory device 100, for example, one word line pick-up region 103 between two core array regions 101 in the x-direction, in other examples. It is also understood that FIG. 1 only illustrates portions of core array region 101 that are adjacent to word line pick-up region 103.

As described below in detail, word line pick-up region 103 can include conductive portions 105 and dielectric portions 107 arranged in the y-direction. As shown in FIG. 1, contact structures 106 are disposed in dielectric portion 107, while dummy channel structures 112 are disposed in conductive portion 105 of word line pick-up region 103 to provide mechanical support and/or load balancing, according to some implementations. In some implementations, dummy channel structures 112 are disposed in dielectric portion 107 of word line pick-up region 103 as well, for example, between contact structures 106 in the x-direction. In some other implementations, dummy channel structures 112 are not disposed in dielectric portion 107 of word line pick-up region 103, i.e., only in conductive portion 105 of word line pick-up region 103. As shown in FIG. 1, each finger 104 of 3D memory device 100 can include one row of contact structures 106 disposed in dielectric portion 107 of word line pick-up region 103. It is understood that the layout and arrangement of contact structures 106, as well as the shape of each contact structure 106, may vary in different examples.

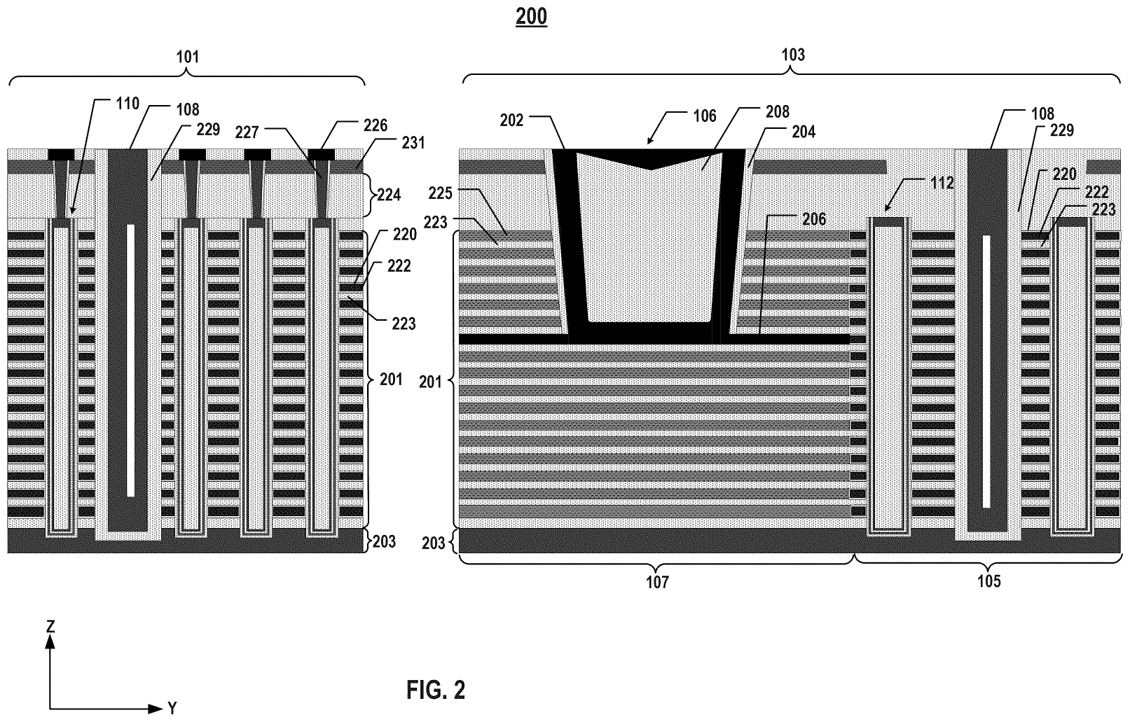

FIG. 2 illustrates cross-sectional side views of a 3D memory device 200 having contact structures 106, according to some examples of the present disclosure. 3D memory device 200 can be an example implementation of 3D memory device 100 of FIG. 1. One cross-section may be along the BB direction in core array region 101 in FIG. 1, and another cross-section may be along the CC direction in word line pick-up region 103 in FIG. 1.

As shown in FIG. 2, a stack structure 201 can be formed on a substrate 203, which can include silicon (e.g., single crystalline silicon), silicon germanium (SiGe), gallium arsenide (GaAs), germanium (Ge), silicon on insulator (SOI), or any other suitable materials. In some implementations, substrate 203 includes single crystalline silicon, which is part of the wafer on which 3D memory device 200 is fabricated, either in its native thickness or being thinned. In some implementations, substrate 203 includes, for example, polysilicon, which is a semiconductor layer replacing the part of wafer on which 3D memory device 200 is fabricated. It is noted that y and z axes are included in FIG. 2 to further illustrate the spatial relationship of the components in 3D memory device 200. Substrate 203 of 3D memory device 200 includes two lateral surfaces extending laterally in the x-y plane: a top surface on the front side of the wafer on which stack structure 201 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of 3D memory device 200 is determined relative to substrate 203 of 3D memory device 200 in the z-direction (the vertical direction perpendicular to the x-y plane) when substrate 203 is positioned in the lowest plane of 3D memory device 200 in the z-direction. The same notion for describing the spatial relationship is applied throughout the present disclosure.

Stack structure 201 may include a first portion and a second portion. For example, the first portion of stack structure 201 may include a first part of stack structure 201 in dielectric portion 107 of word line pick-up region 103. The second portion of stack structure 201 may include a second part of stack structure 201 in conductive portion 105 of word line pick-up region 103 and a third part of stack structure 201 in core array region 101.

As shown in FIG. 2, stack structure 201 can include vertically interleaved first layers and first dielectric layer 223. First layers and first dielectric layer 223 can alternate in the vertical direction (the z-direction). In some implementations, stack structure 201 can include a plurality of layer pairs stacked vertically in the z-direction, each of which includes a first layer and a first dielectric layer 223. The number of the layer pairs in stack structure 201 can determine the number of memory cells in 3D memory device 200.

In some implementations, 3D memory device 200 is a NAND Flash memory device, and stack structure 201 is a stacked storage structure through which NAND memory strings are formed. As shown in FIG. 2, the first layers can have different materials in different regions/portions of 3D memory device 200. For example, the first layers may include second dielectric layers 225 in the first portion of stack structure 201. That is, the first portion of stack structure 201 (in dielectric portion 107 of word line pick-up region 103) may include interleaved second dielectric layers 225 and first dielectric layers 223. The first layers may include conductive layers 222 in the second portion of stack structure 201. That is, the second portion of stack structure 201 (in core array region 101 and conductive portion 105 of word line pick-up region 103) may include interleaved conductive layers 222 and first dielectric layers 223.

In some implementations, each conductive layer 222 in core array region 101 and conductive portion 105 of word line pick-up region 103 functions as a gate line of the NAND memory strings (in the forms of channel structures 110) in core array region 101, as well as a word line extending laterally from the gate line and ending in conductive portion 105 of word line pick-up region 103 for word line pick-up/fan-out through contact structures 106. The word lines (i.e., conductive layers 222) at different depths/levels each extend laterally in core array region 101 and conductive portion 105 of word line pick-up region 103, but are discontinuous (e.g., being replaced by second dielectric layers 225) in dielectric portion 107 of word line pick-up region 103, according to some implementations.

Conductive layers 222 can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. The dielectric layers can include dielectric materials including, but not limited to, silicon oxide, silicon nitride, silicon oxynitride, or any combination thereof. First dielectric layers 223 and second dielectric layers 225 can have different dielectric materials, such as silicon oxide and silicon nitride. In some implementations, conductive layers 222 include metals, such as tungsten, first dielectric layers 223 include silicon oxide, and second dielectric layers 225 include silicon nitride. For example, first dielectric layers 223 of stack structure 201 may include silicon oxide across core array region 101 and word line pick-up region 103; conductive layers 222 of stack structure 201 may include tungsten in core array region 101 and conductive portion 105 of word line pick-up region 103; and second dielectric layers 225 of stack structure 201 may include silicon nitride in dielectric portion 107 of word line pick-up region 103.

As shown in FIG. 2, 3D memory device 200 can include channel structures 110 in core array region 101. Each channel structure 110 can extend vertically through interleaved conductive layers 222 (word lines, e.g., tungsten) and first dielectric layers 223 (e.g., silicon oxide) in stack structure 201 into substrate 203. 3D memory device 200 can also include dummy channel structures 112 in conductive portion 105 of word line pick-up region 103. Each dummy channel structure 112 can extend vertically through interleaved conductive layers 222 and first dielectric layers 223 of stack structure 201 into substrate 203. 3D memory device 200 can further include slit structures 108 across core array region 101 and word line pick-up region 103. Each slit structure 108 can extend vertically through interleaved conductive layers 222 and first dielectric layers 223 of stack structure 201 into substrate 203 as well.

As shown in FIG. 2, slit structure 108 can include a slit spacer 229 that separates conductive layers 222 (word lines) between different blocks 102. In some implementations, slit structure 108 is an insulating structure that does not include any contact therein (i.e., not functioning as the source contact) and thus, does not introduce parasitic capacitance and leakage current with conductive layers 222 (word lines). In some implementations, slit structure 108 is a front-side source contact further including a conductive portion (e.g., including W, polysilicon, and/or TiN) circumscribed by slit spacer 229. As described below in detail, during the gate line replacement process, a slit opening in which slit structure 108 is formed can serve as the passageway and starting point for forming conductive layers 222. As a result, slit structure 108 is surrounded by conductive layers 222 in either core array region 101 or conductive portion 105 of word line pick-up region 103.

As shown in FIG. 2, in some implementations, 3D memory device 200 further includes a plurality of drain select gate (DSG) channel structures 227 above and in contact with the upper ends of channel structures 110, respectively. 3D memory device 200 can further include a DSG layer 224 including a semiconductor layer (e.g., polysilicon layer) on stack structure 201 in core array region 101, but not in word line pick-up region 103, for example, as shown in FIG. 2. Each DSG channel structure 227 can extend vertically through DSG layer 224 to be in contact with the upper end of a corresponding channel structure 110. In some implementations, 3D memory device 200 further includes a stop layer 231 (e.g., silicon nitride layer) on DSG layer 224. DSG channel structure 227 can include a semiconductor layer (e.g., polysilicon) and a spacer surrounding the semiconductor layer. In some implementations, 3D memory device 200 includes a DSG stack including one or more DSG layers and one or more dielectric layers (e.g., silicon oxide layers) stacked above stack structure 201.

As shown in FIG. 2, 3D memory device 200 can further include a local contact layer above stop layer 231 and stack structure 201. In some implementations, the local contact layer includes various local contacts, such as channel contacts 226 (a.k.a. bit line contacts) above and in contact with DSG channel structures 227 in core array region 101. The local contact layer can further include one or more interlayer dielectric (ILD) layers (also known as “intermetal dielectric (IMD) layers”) in which the local contacts can form. Channel contacts 226 in the local contact layer can include conductive materials including, but not limited to, W, Co, Cu, Al, silicides, or any combination thereof. The ILD layers in the local contact layer can include dielectric materials including, but not limited to, silicon oxide, silicon nitride, silicon oxynitride, low-k dielectrics, or any combination thereof.

Instead of having staircase structures and word line contacts landed on different levels/stairs of the staircase structures, 3D memory device 200 can include stack structure 201 with uniform heights and contact structures 106 in dielectric portion 107 of word line pick-up region 103 for word line pick-up/fan-out. Each contact structure 106 may include a vertical contact member 202, a contact spacer 204 circumscribing vertical contact member 202, and a lateral contact member 206 below and in contact with vertical contact member 202. Vertical contact member 202 and lateral contact member 206 can include conductive materials including, but not limited to, W, Co, Cu, Al, TiN, polysilicon, doped silicon, silicides, or any combination thereof. Contact spacer 204 can include dielectric materials including, but not limited to, silicon oxide, silicon nitride, silicon oxynitride, or any combination thereof. In some implementations, vertical contact member 202 and lateral contact member 206 include TiN/W, and contact spacer 204 includes silicon oxide.

In some implementations as shown in FIG. 2, contact structure 106 further includes a filler body 208 circumscribed by vertical contact member 202. That is, a contact opening of contact structure 106 may not be fully filled with contact spacer 204 and vertical contact member 202, and the remaining space of the contact opening may be filled with dielectric materials, including, but not limited to, silicon oxide, silicon nitride, silicon oxynitride, or any combination thereof, as filler body 208.

As shown in FIG. 2, lateral contact member 206 of each contact structure 106 in dielectric portion 107 can extend laterally in the y-direction (the bit line direction) to be in contact with a corresponding conductive layer 222 (word line) in conductive portion 105 at the same level as stack structure 201. Since lateral contact member 206 is in contact with vertical contact member 202 of contact structure 106, each contact structure 106 is electrically connected to corresponding conductive layer 222 (word line) across conductive portion 105 in word line pick-up region 103 and core array region 101, according to some implementations. In other words, contact structures 106 can extend vertically through stack structure 201 at different depths to be electrically connected to the word lines at different levels, respectively, to achieve word line pick-up/fan-out.

As described below in detail, during the gate line replacement process, some of second dielectric layers 225 (e.g., silicon nitride) remain intact in dielectric portion 107 of word line pick-up region 103, and contact structure 106 is formed by etching first and second dielectric layers 223 and 225 in dielectric portion 107 of word line pick-up region 103. As a result, contact structures 106 extend into interleaved first and second dielectric layers 223 and 225 and are surrounded by first and second dielectric layers 223 and 225 in dielectric portion 107 of word line pick-up region 103. The bottom of each contact structure 106 can be aligned with a corresponding second dielectric layer 225, as opposed to first dielectric layer 223, and the corresponding second dielectric layer 225 can be partially replaced with lateral contact member 206 to form the electrical connection between vertical contact member 202 of contact structure 106 and the corresponding conductive layer 222 (word line). Thus, in some implementations, lateral contact member 206 is sandwiched between two first dielectric layers 223, as opposed to two second dielectric layers 225, in dielectric portion 107 of word line pick-up region 103.

As shown in FIG. 2, 3D memory device 200 can further include high dielectric constant (high-k) gate dielectric layers 220 each sandwiched between adjacent conductive layer 222 and first dielectric layer 223 in core array region 101 and conductive portion 105 of word line pick-up region 103. As described below in detail with respect to the fabrication process, high-k gate dielectric layers 220 may be formed prior to the formation of conductive layers 222, such that conductive layers 222 may be formed surrounded by high-k gate dielectric layers 220. High-k gate dielectric layers 220 can include high-k dielectric materials, such as aluminum oxide (AlO), hafnium oxide (HfO), zirconium oxide (ZrO), or any combinations thereof.

Compared with other high-k gate dielectric layers 220, part of high-k gate dielectric layers 220 surrounding a corresponding conductive layer 222 (part of word line) that is in contact with lateral contact member 206 is removed to expose conductive layer 222 such that lateral contact member 206 can be electrically connected to conductive layer 222. However, as described below in more detail with reference to FIGS. 3B-3C, high-k gate dielectric layers 220 surrounding the corresponding conductive layer 222 may be over-etched during the fabrication process, causing damage to high-k gate dielectric layers 220 surrounding the corresponding conductive layer 222. If high-k gate dielectric layers 220 surrounding the corresponding conductive layer 222 is over etched too much, slit spacer 229 of slit structure 108 can also be damaged.

A brief description for the fabrication process of 3D memory device 200 is provided herein. Initially, stack structure 201 including interleaved first dielectric layers 223 and second dielectric layers 225 is formed. Channel structures 110 extending through first dielectric layers 223 and second dielectric layers 225 are formed in core array region 101. Dummy channel structures 112 can be formed in word line pick-up region 103 of stack structure 201, in the same process as forming channel structures 110. DSG layer 224 and stop layer 231 are formed on core array region 101 of stack structure 201.

Next, all the second dielectric layers 225 in core array region 101 and parts of the second dielectric layers 225 in word line pick-up region 103 are replaced with conductive layers 222, for example, by a gate line replacement process through slit openings. High-k gate dielectric layers 220 may be formed prior to the formation of conductive layers 222, such that conductive layers 222 may be formed surrounded by high-k gate dielectric layers 220. Slit structures 108 including slit spacers 229 can be formed in the slit openings. Each slit structure 108 may extend vertically through interleaved conductive layers 222 and first dielectric layers 225 of stack structure 201 (as shown in FIG. 2) and laterally across core array region 101 and conductive portion 105 of word line pick-up region 103 (as shown in FIG. 1).

Subsequently, contact structures 106 extending through first dielectric layers 223 and remainders of second dielectric layers 225 in dielectric portion 107 are formed at different depths, such that contact structures 106 are electrically connected to conductive layers 222, respectively, in dielectric portion 107. For example, with reference to FIG. 3A, contact openings 302 extending through first dielectric layers 223 and the remainders of second dielectric layers 225 in dielectric portion 107 are formed at different depths to expose the remainders of second dielectric layers 225 in dielectric portion 107, respectively. For each contact opening 302, a contact spacer 204 can be formed on sidewalls and a bottom of contact opening 302. A part of contact spacer 204 on the bottom of contact opening 302 is removed to expose the respective part of the remainder of a corresponding second dielectric layer 225. As shown in FIG. 3B, the exposed part of the remainder of the corresponding second dielectric layer 225 is etched by applying a wet etchant through contact opening 302 to form a lateral recess 312, such that the respective conductive layer 222 in the first portion of stack structure 201 is exposed.

However, as shown in FIG. 3C which illustrates an enlarged view of a part 314 of FIG. 3B, when the part of the corresponding second dielectric layer 225 is etched away by the wet etchant, high-k gate dielectric layers 220 surrounding the respective conductive layer 222 may also be over etched by the wet etchant. For example, not only a high-k gate dielectric layer 220 on an end surface 317 of the respective conductive layer 222 is etched away, but also high-k gate dielectric layers 220 surrounding the respective conductive layer 222 in spaces 316 and 318 are also etched away, resulting in damage in high-k gate dielectric layers 220 surrounding the respective conductive layer 222. If high-k gate dielectric layers 220 surrounding the respective conductive layer 222 is etched all the way through spaces 316 and 318, slit spacer 229 of slit structure 108 can also be damaged.

It can be difficult to find an appropriate wet etchant or develop a new wet etchant that can be controlled to only etch the corresponding second dielectric layer 225 (including silicon nitride) without over-etching high-k gate dielectric layers 220 surrounding the respective conductive layer 222. Further, it can also be difficult to control an etching rate and/or etching time to remove only the part of the corresponding second dielectric layer 225 that is enough to expose end surface 317 of the respective conductive layer 222, without over-etching high-k gate dielectric layers 220 in spaces 316 and 318.

To solve the over-etching issue of high-k gate dielectric layers 220, a high-k dielectric material may be deposited through lateral recess 312 to fill in spaces 316 and 318, so that the damage previously made to high-k gate dielectric layers 220 surrounding the respective conductive layer 222 is repaired. In this case, a new high-k gate dielectric layer is also formed and covers end surface 317 of the respective conductive layer 222 again. Then, the new high-k gate dielectric layer formed on end surface 317 of the respective conductive layer 222 can be removed to expose end surface 317 of the respective conductive layer 222. Subsequently, lateral contact member 206 can be formed in lateral recess 312 in contact with end surface 317 of the respective conductive layer 222; vertical contact member 202 may be formed on a sidewall of contact spacer 204; and filler body 208 may be formed to fill in the remaining space of contact opening 302. In this way, contact structure 106 of FIG. 2 may be formed. However, since (a) additional high-k dielectric material needs to be deposited into spaces 316 and 318 to repair the damage previously made to high-k gate dielectric layers 220 and (b) the new high-k gate dielectric layer formed on end surface 317 of the respective conductive layer 222 needs to be etched back again, the manufacturing process of 3D memory device 200 becomes more complicated, and the cost of 3D memory device 200 can be increased.

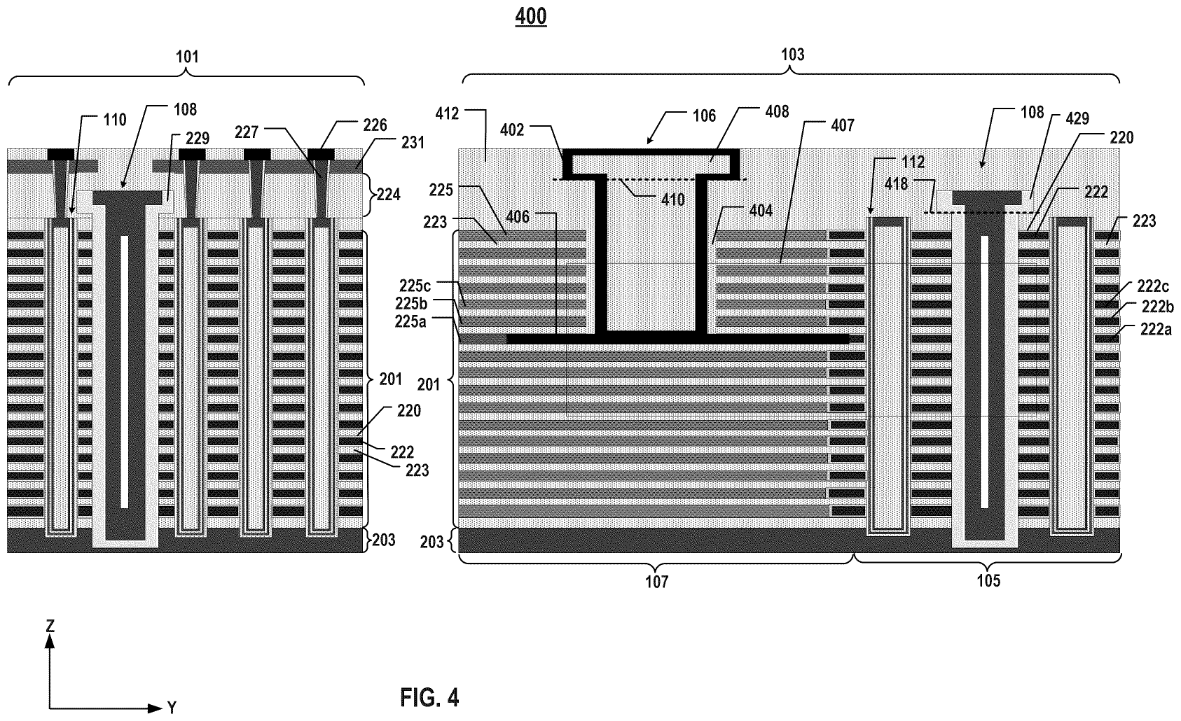

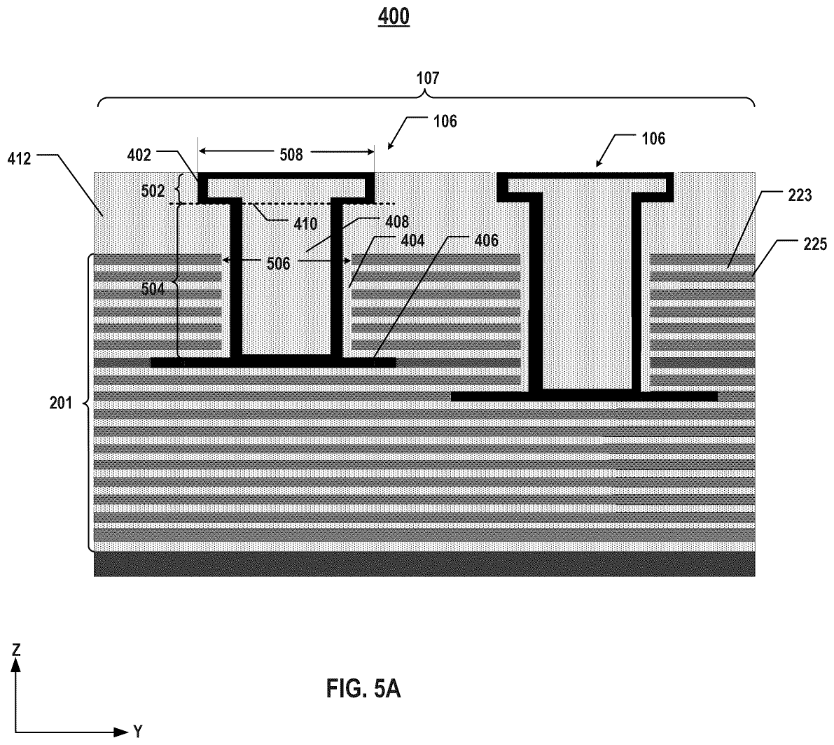

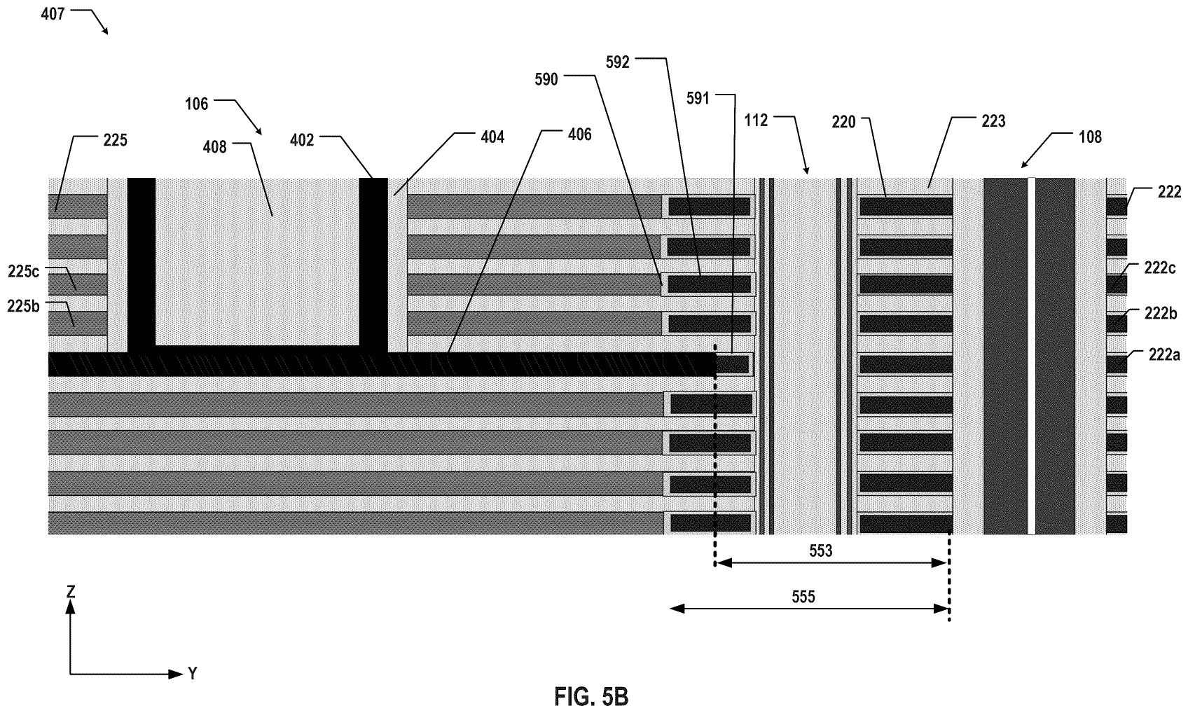

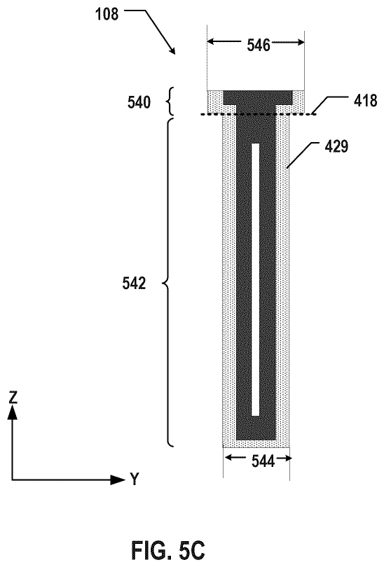

FIG. 4 illustrates cross-sectional side views of a 3D memory device 400 having contact structures 106, according to some aspects of the present disclosure. FIG. 5A illustrates a cross-sectional side view of 3D memory device 400 of FIG. 4, according to some aspects of the present disclosure. FIG. 5B illustrates an enlarged cross-sectional side view of a part 407 of 3D memory device 400 in FIG. 4, according to some aspects of the present disclosure. FIG. 5C illustrates a slit structure 108 in 3D memory device 400 of FIG. 4, according to some aspects of the present disclosure. FIGS. 4 and 5A-5C are described below together.

3D memory device 400 can be an example implementation of 3D memory device 100 of FIG. 1. In FIG. 4, one cross-section may be along the BB direction in core array region 101 in FIG. 1, and another cross-section may be along the CC direction in word line pick-up region 103 in FIG. 1. 3D memory device 400 of FIG. 4 may include components and structures like those of 3D memory device 200 of FIG. 2, and the similar description will not be repeated herein.

In some implementations, 3D memory device 400 may include a semiconductor layer (e.g., substrate 203), stack structure 201 over the semiconductor layer, and a third dielectric layer 412 over stack structure 201 in word line pick-up region 103. Third dielectric layer 412 can include dielectric materials including, but not limited to, silicon oxide, silicon nitride, silicon oxynitride, or any combination thereof.

Consistent with some aspects of the present disclosure, contact structure 106 of 3D memory device 400 in FIG. 4 may have a structure different from contact structure 106 of 3D memory device 200 in FIG. 2. As shown in FIG. 4, contact structure 106 may include a vertical contact member 402 extending in a first direction (e.g., the z-direction), a lateral contact member 406 connecting to vertical contact member 402 and extending in a second direction (e.g., the y-direction), and a spacer 404 surrounding at least a part of vertical contact member 402. In some implementations, contact structure 106 may further include a filler body 408 surrounded by vertical contact member 402. A local contact may also be formed on a top surface of filler body 408. Lateral contact member 406 may connect with a first one of conductive layers 222 (e.g., conductive layer 222a).

Contact structure 106 in FIG. 4 may extend through third dielectric layer 412 and a part of the first portion of stack structure 201 to connect with the first one of conductive layers 222. For example, as illustrated in FIG. 5A, the cross-section may be along the AA direction in dielectric portion 107 of word line pick-up region 103 in FIG. 1. Contact structure 106 may include a first contact segment 502 and a second contact segment 504, which are connected with each other at a first joint region 410 in third dielectric layer 412. First contact segment 502 may extend through a first part of third dielectric layer 412 in the first direction, and second contact segment 504 may extend through a second part of third dielectric layer 412 and a part of the first portion of stack structure 201 in the first direction. A size 508 of first contact segment 502 can be greater than a size 506 of second contact segment 504 in the second direction perpendicular to the first direction. First contact segment 502 may include a first part of vertical contact member 402 and a first part of filler body 408. Second contact segment 504 may include spacer 404, a second part of vertical contact member 402, and a second part of filler body 408. The first part and the second part of vertical contact member 402 may connect with each other at first joint region 410 in third dielectric layer 412. The first part and the second part of filler body 408 may connect with each other at first joint region 410 in third dielectric layer 412.

As shown in FIGS. 4 and 5A, each of first contact segment 502 and second contact segment 504 may have a rectangular shape. In some implementations, each of first contact segment 502 and second contact segment 504 may have any other suitable shape, such as a trapezoidal shape, a square shape, etc., which is not limited herein.

As shown in FIG. 5A, different contact structures 106 may extend vertically into stack structure 201 (in dielectric portion 107 of word line pick-up region 103) at different depths in the z-direction, according to some implementations. The top surfaces of different contact structures 106 can be flush with one another, while the bottom surfaces of different contact structures 106 can extend to different levels, for example, different second dielectric layers 225 of stack structure 201.

With reference to FIGS. 4, second dielectric layers 225 in the first portion of stack structure 201 (in dielectric portion 107 of word line pick-up region 103) may include: (1) a first one of second dielectric layers 225 (e.g., second dielectric layer 225a) at a same level as the first one of conductive layers 222 (e.g., conductive layer 222a) which is connected to lateral contact member 406; and (2) second ones of second dielectric layers 225 (e.g., second dielectric layers 225b, 225c) at the same levels of second ones of conductive layers 222 (e.g., conductive layers 222b, 222c), respectively. Lateral contact member 406 is formed in the first one of second dielectric layers 225. Lateral contact member 406 may protrude into the second portion of stack structure 201 and may connect with the first one of conductive layers 222.

With reference to FIG. 5B, an end surface 590 of each second one of conductive layers 222 can be covered by a first high-k gate dielectric layer 220, and the second one of conductive layers 222 may connect with a respective second one of second dielectric layers 225 via the first high-k gate dielectric layer 220. Side surfaces 591 of the first one of conductive layers 222 (e.g., conductive layer 222a) may be surrounded by second high-k gate dielectric layers 220. Side surfaces 592 of each second one of conductive layers 222 may be surrounded by third high-k gate dielectric layers 220. A first distance 553 from slit structure 108 to the end surface of the first one of conductive layers 222 in the second direction may be smaller than a second distance 555 from slit structure 108 to end surface 590 of the second one of conductive layers 222 in the second direction.

In some implementations, lateral contact member 406 and the first one of conductive layers 222 may include different materials. For example, lateral contact member 406 and the first one of conductive layers 222 may include Titanium nitride and tungsten, respectively.

Consistent with some aspects of the present disclosure, slit structure 108 of 3D memory device 400 in FIG. 4 may have a structure different from slit structure 108 of 3D memory device 200 shown in FIG. 2. For example, with reference to FIGS. 4 and 5C, slit structure 108 may include a first slit segment 540 and a second slit segment 542. First slit segment 540 may extend through a part of third dielectric layer 412, and may include a part of slit spacer 429. Second slit segment 542 may extend through another part of third dielectric layer 412, the first portion of stack structure 201, and a part of substrate 203. Second slit segment 542 may include another part of slit spacer 429. First slit segment 540 may connect with second slit segment 542 at a second joint region 418 in third dielectric layer 412. A size 546 of first slit segment 540 can be greater than a size 544 of second slit segment 542 in the second direction.

As shown in FIGS. 4 and 5C, each of first slit segment 540 and second slit segment 542 may have a rectangular shape. In some implementations, each of first slit segment 540 and second slit segment 542 may have any other suitable shape, such as a trapezoidal shape, a square shape, etc., which is not limited herein.

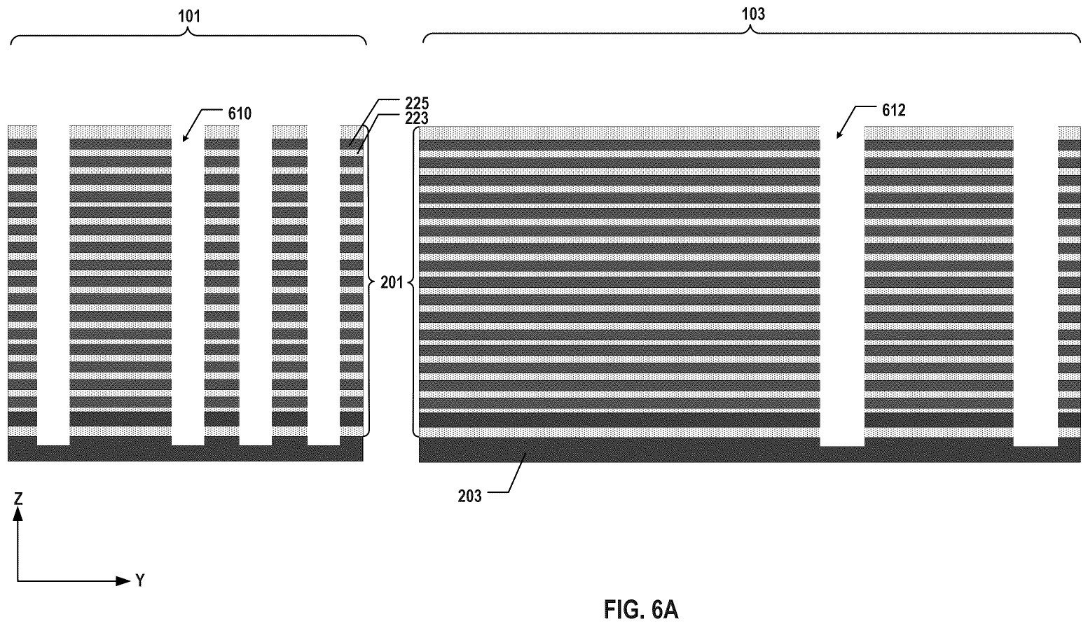

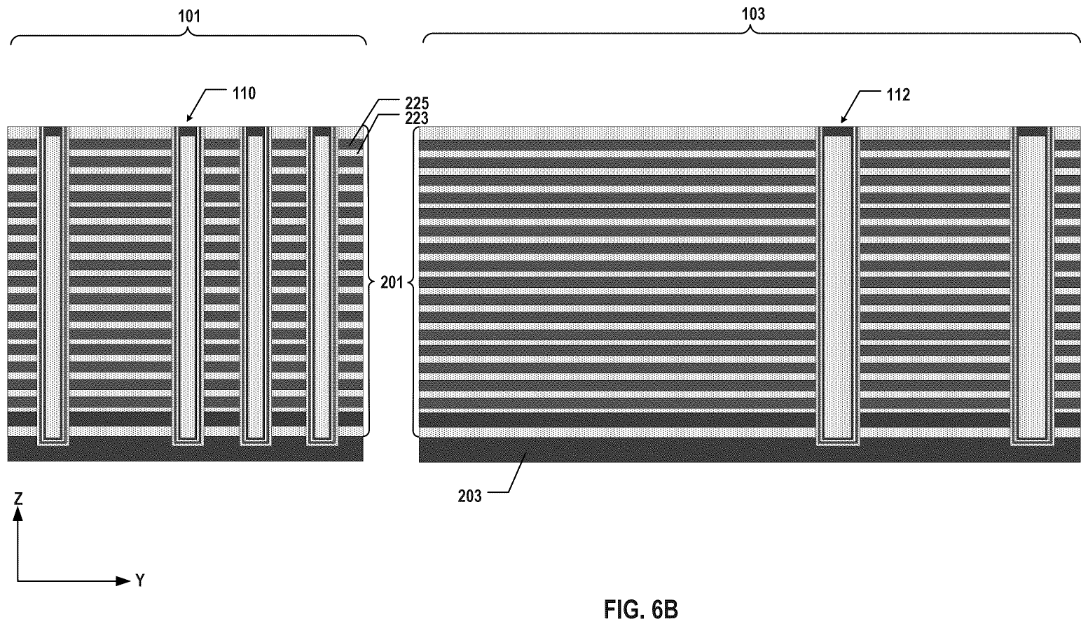

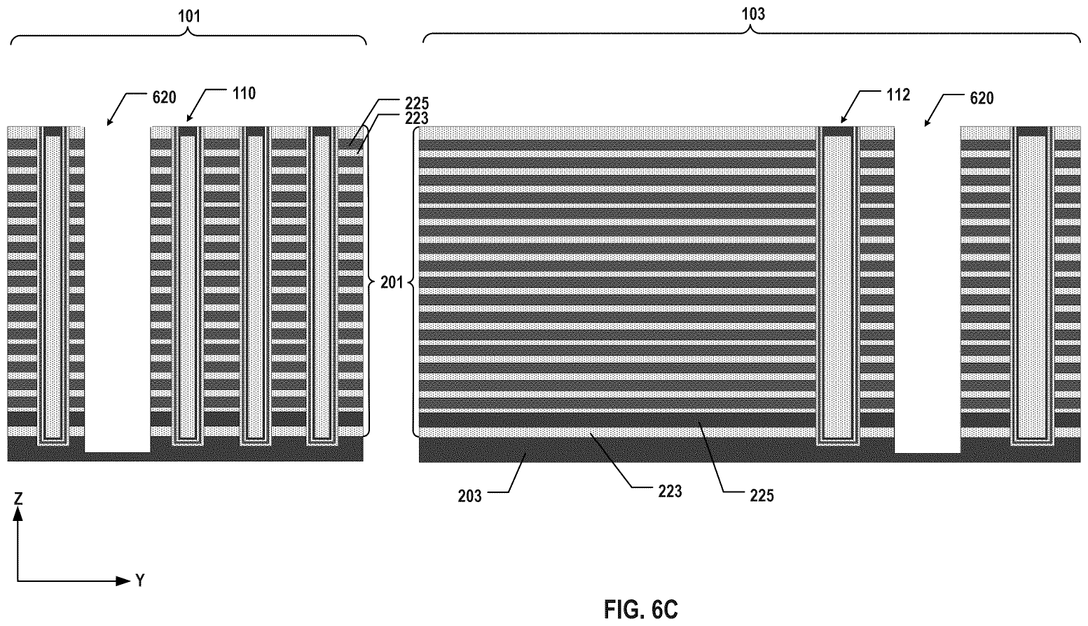

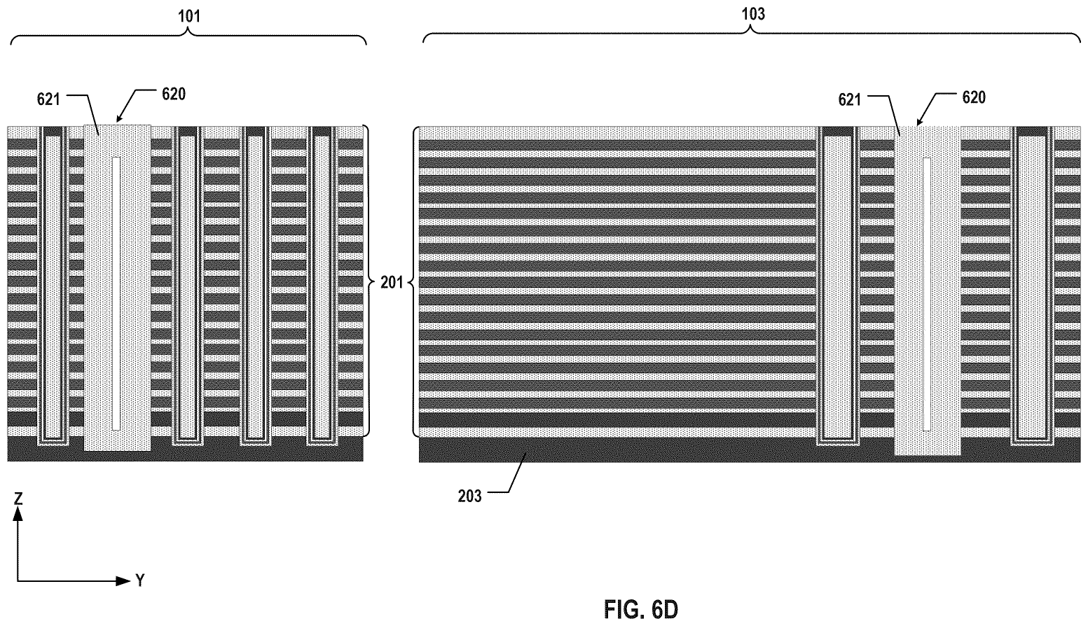

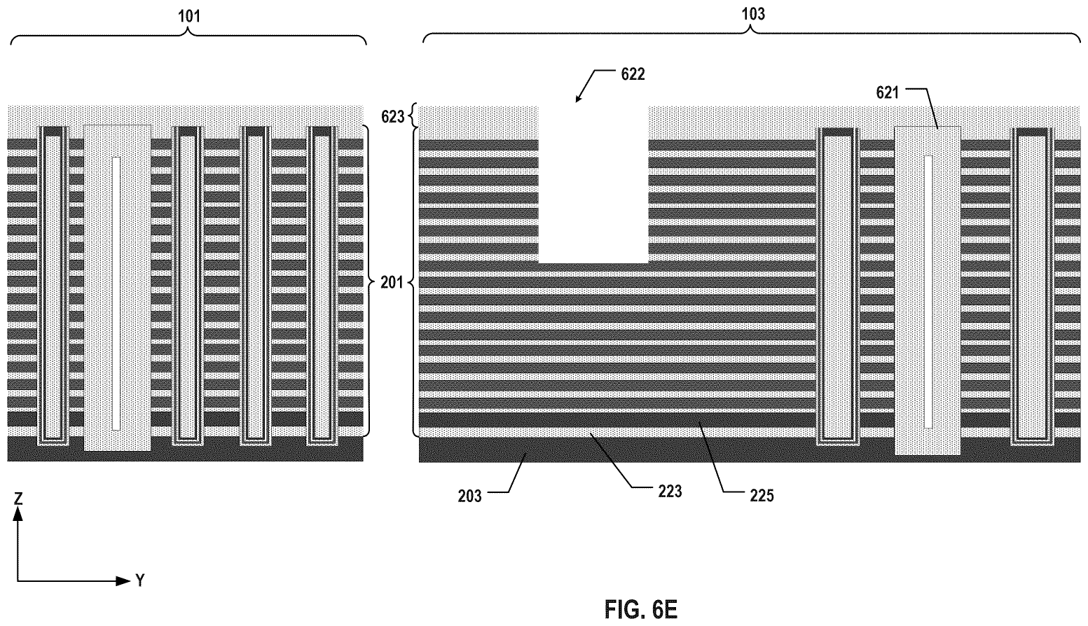

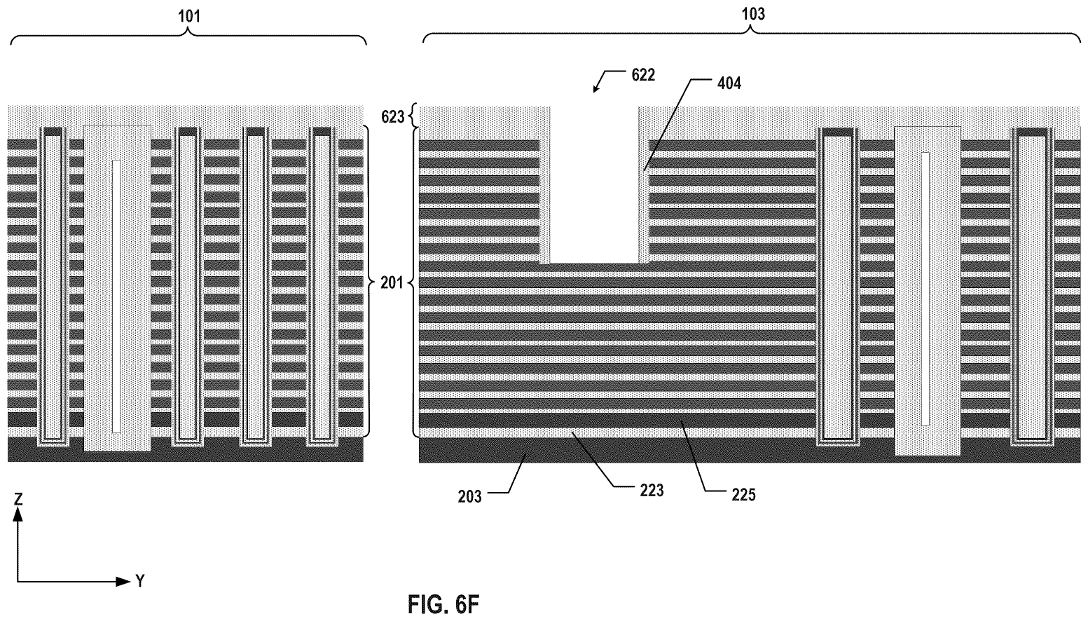

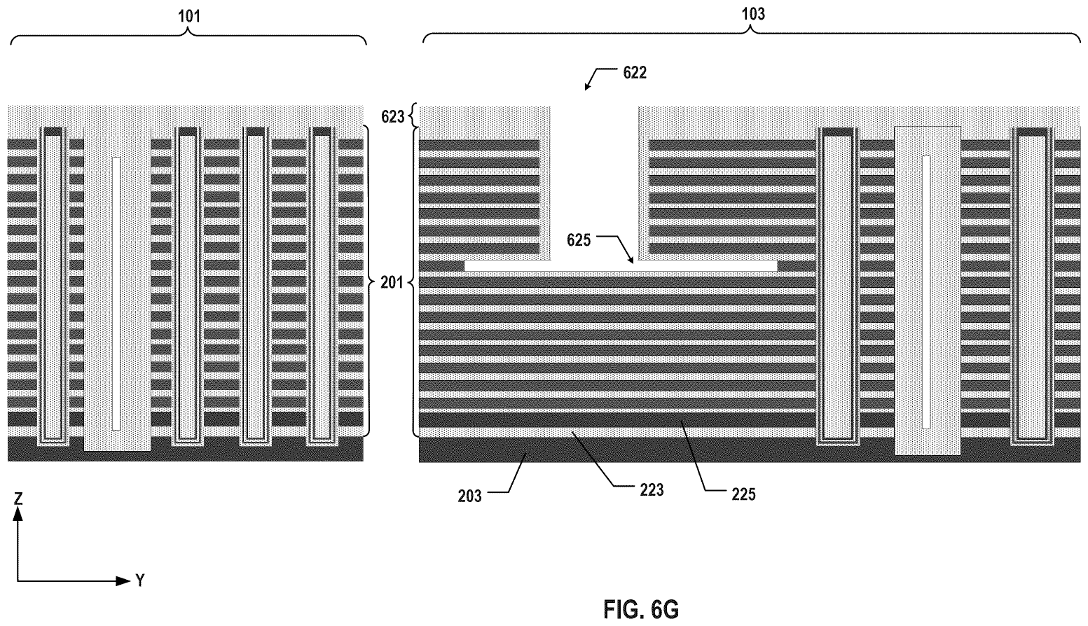

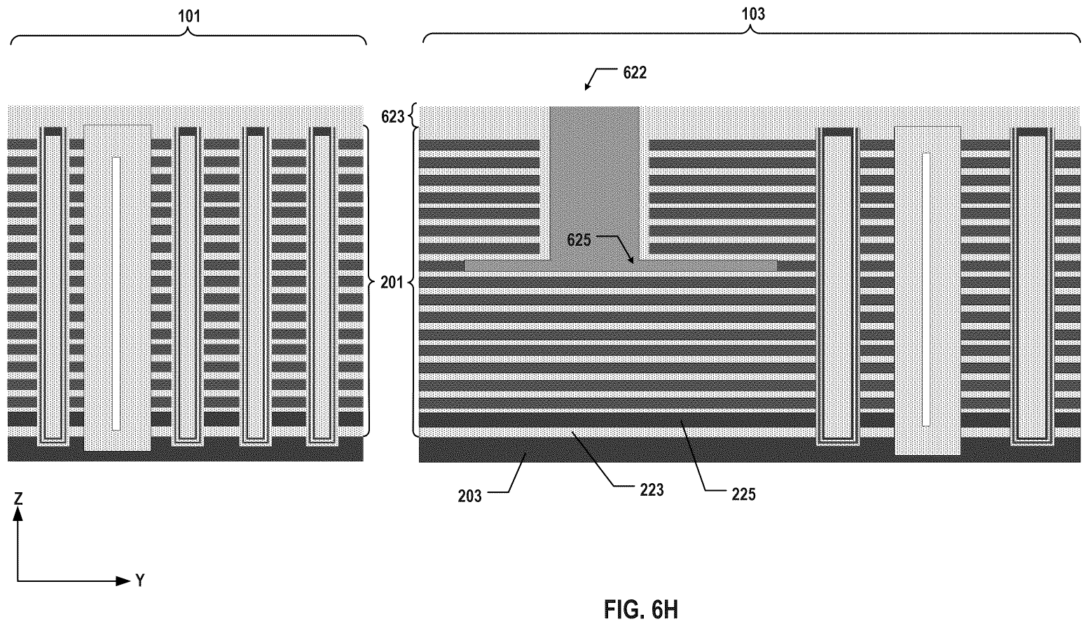

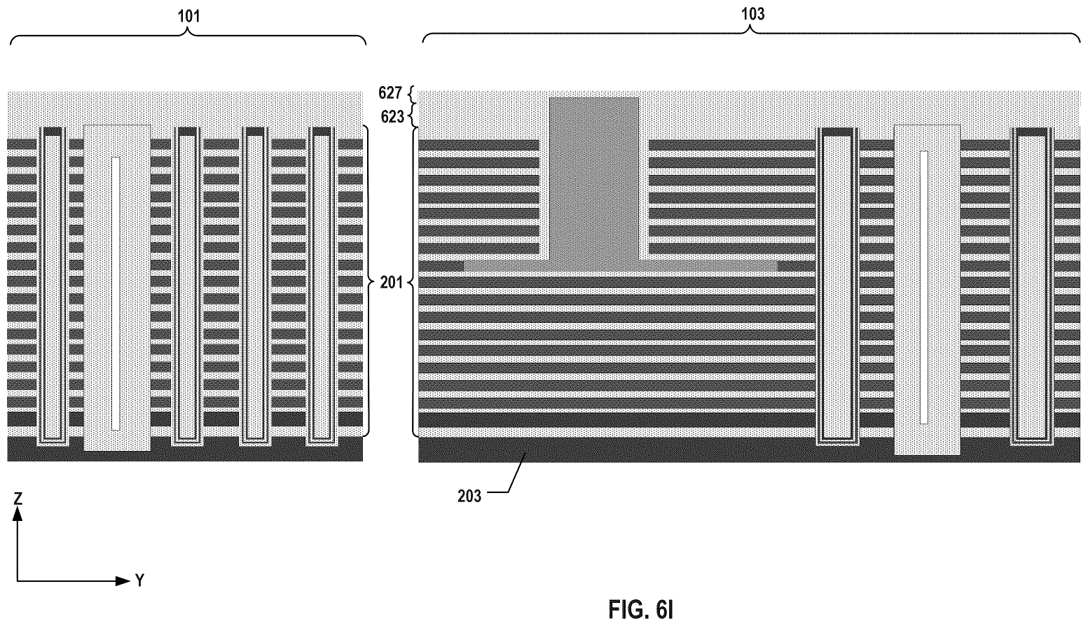

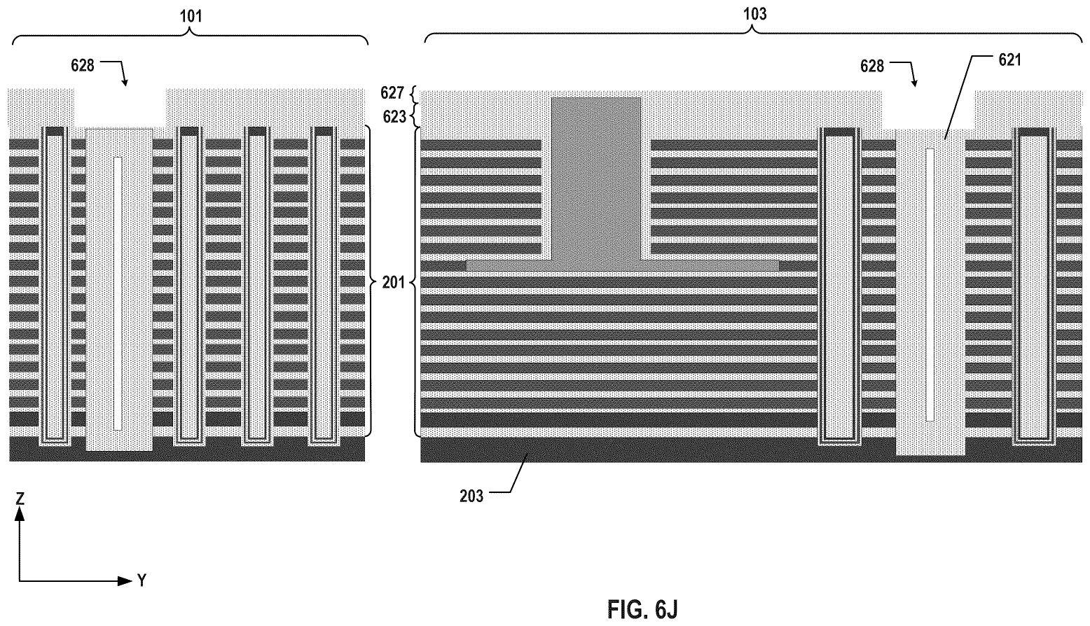

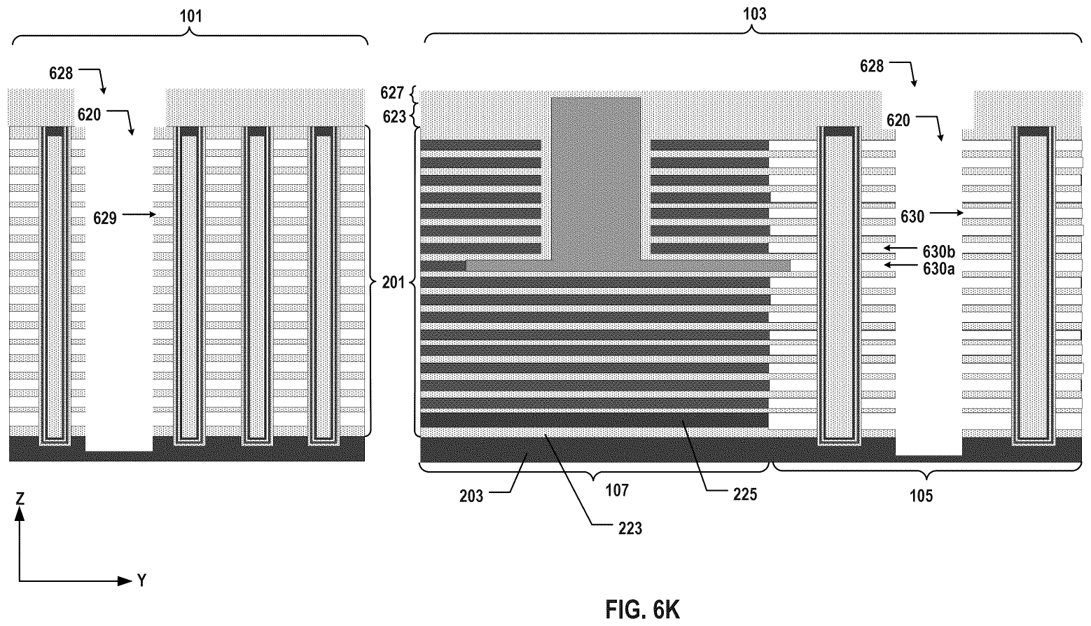

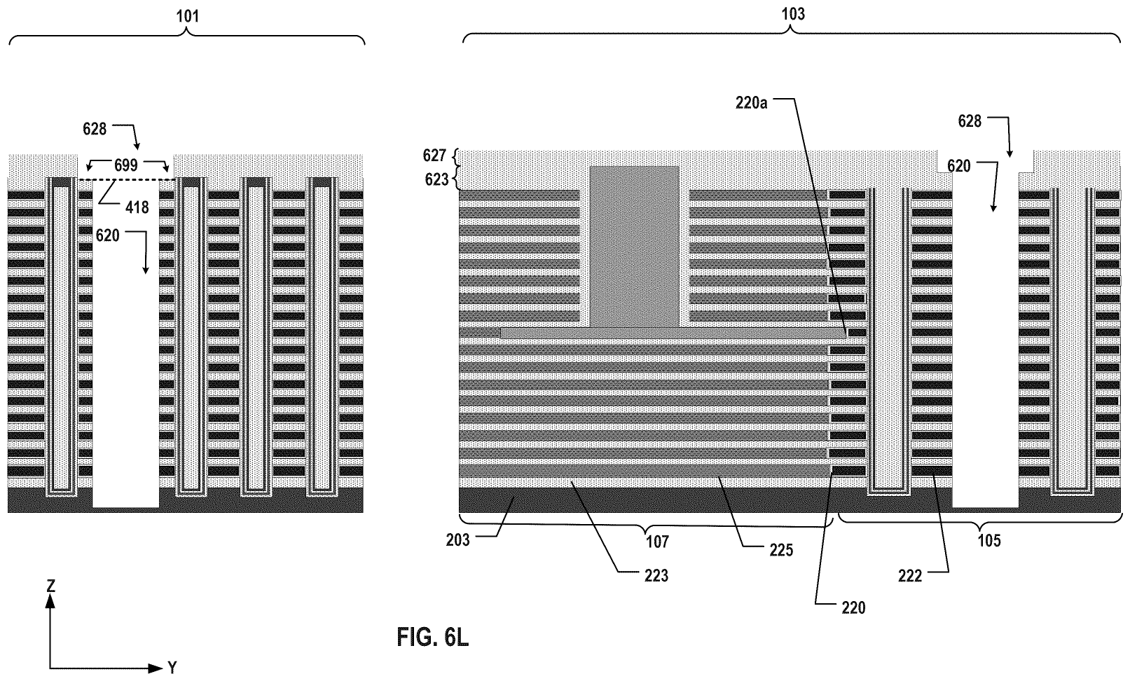

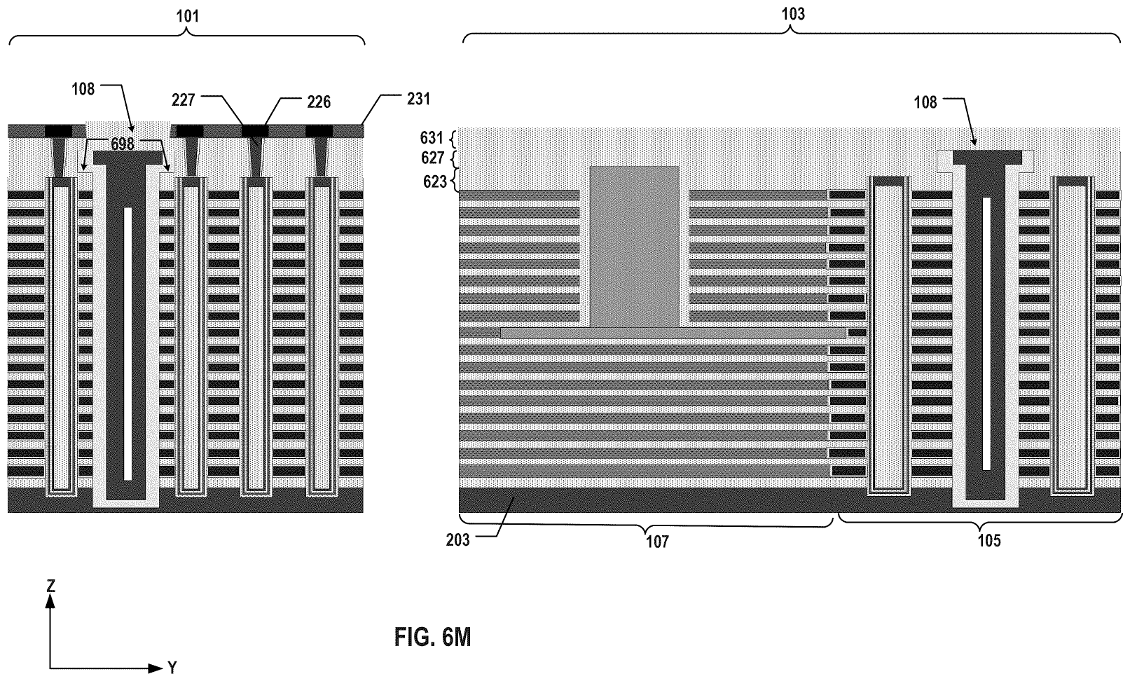

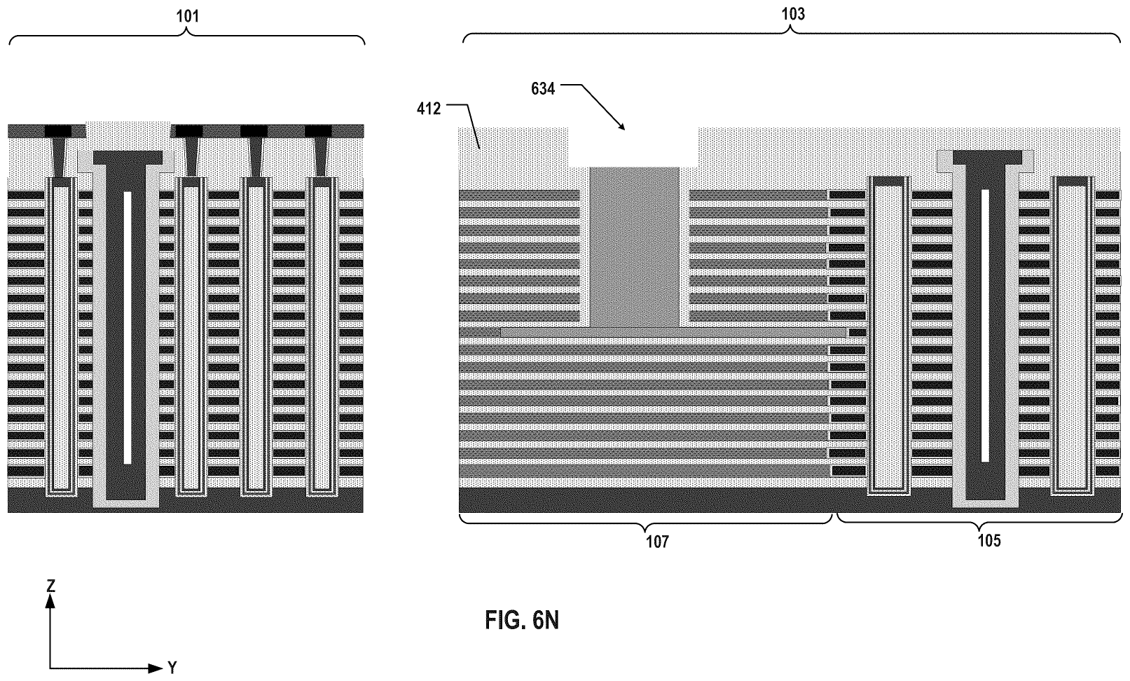

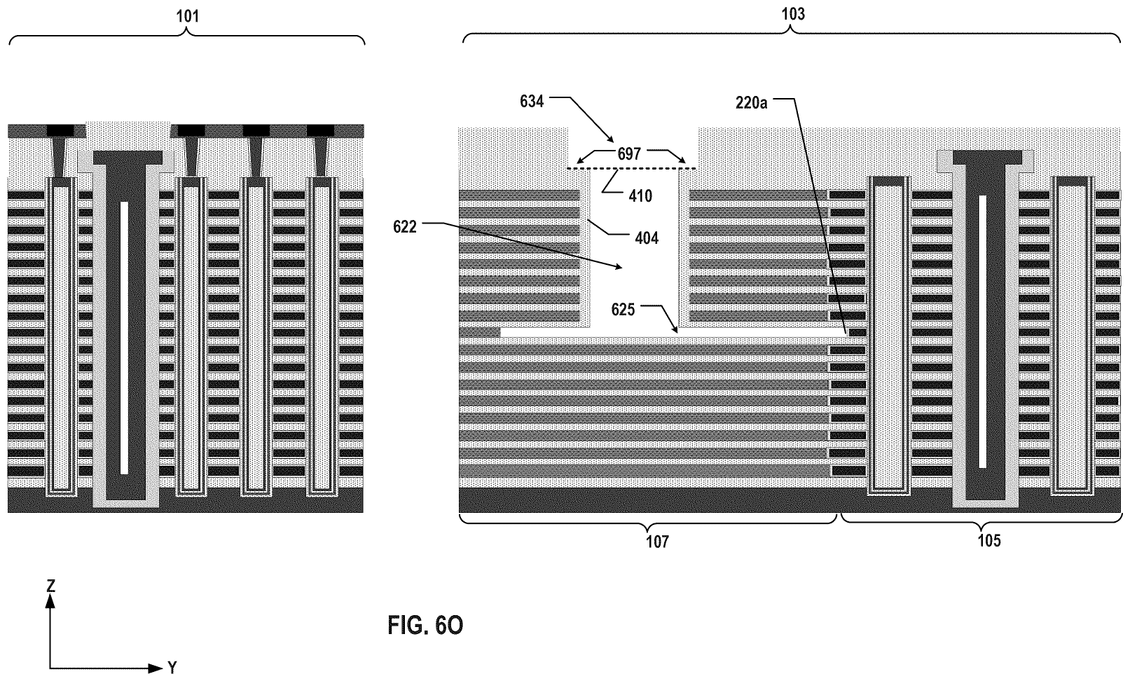

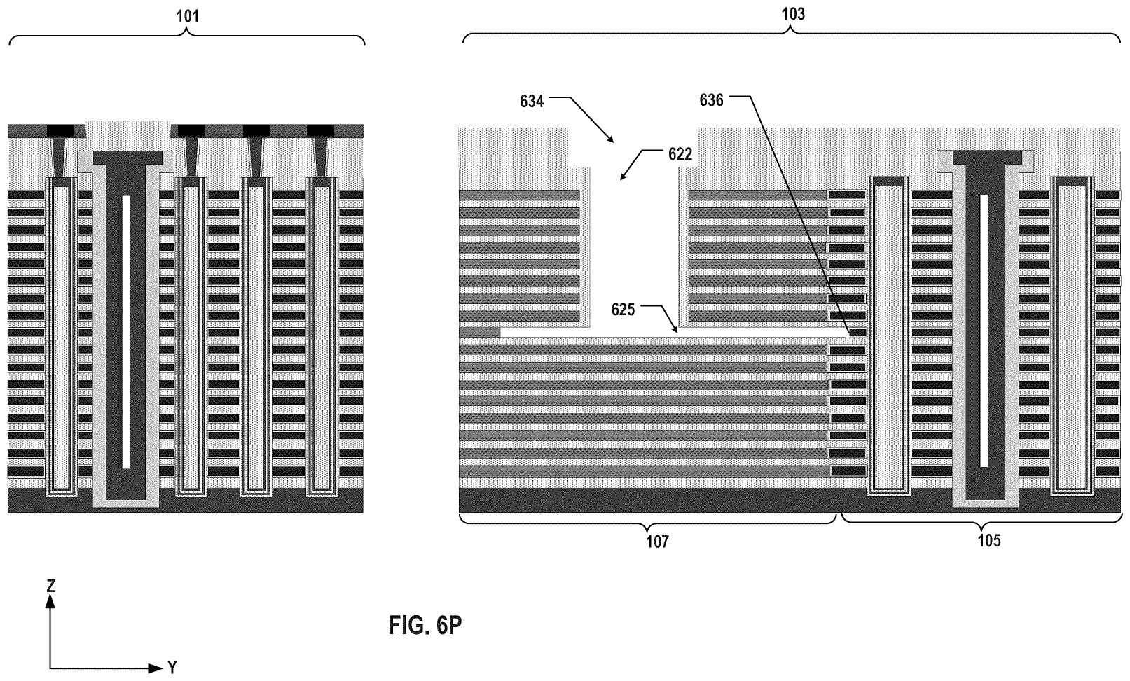

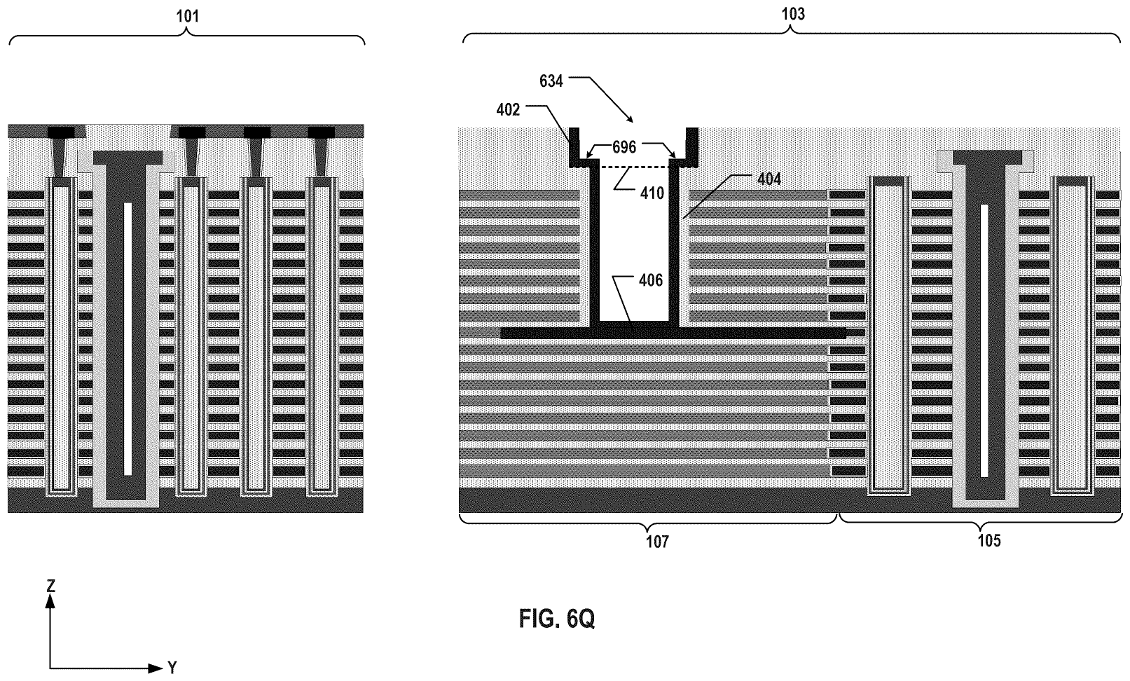

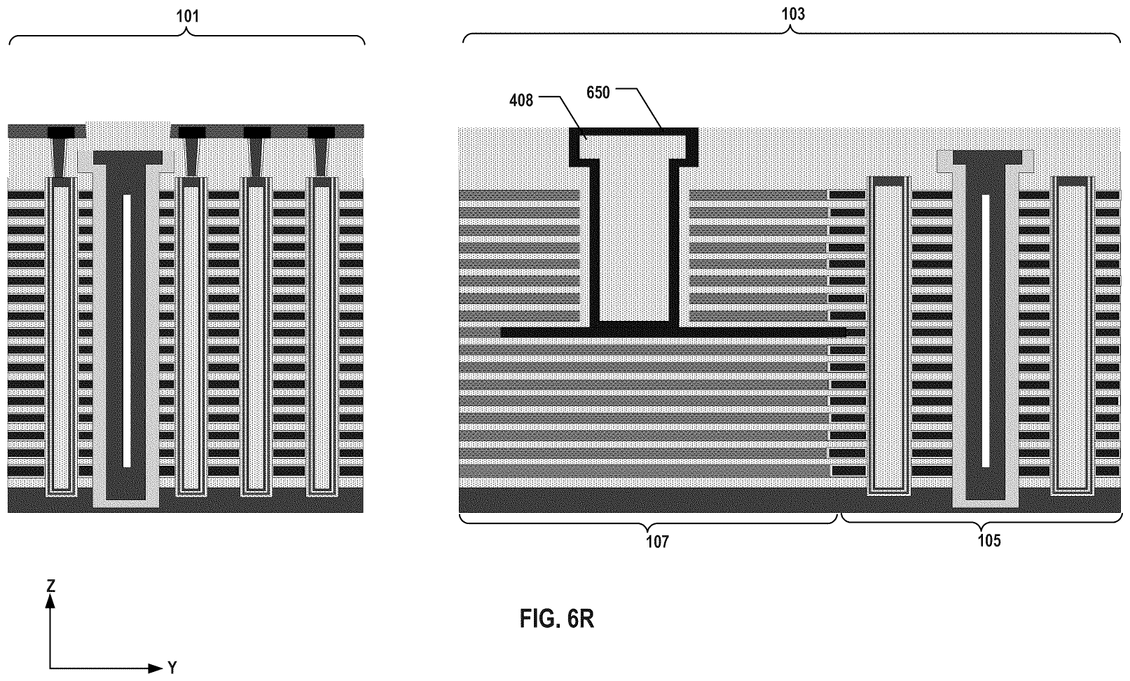

FIGS. 6A-6R illustrate a fabrication process for forming a 3D memory device having contact structures, according to some aspects of the present disclosure. Examples of the 3D memory device depicted in FIGS. 6A-6R include 3D memory devices 100 depicted in FIGS. 1 and 3D memory device 400 depicted in FIGS. 4 and 5A-5C. By way of example, FIGS. 6A-6R are described below with reference to 3D memory device 400.

As illustrated in FIG. 6A, stack structure 201 including multiple pairs of a first dielectric layer 223 and a second dielectric layer 225 (a.k.a., a stack sacrificial layer) is formed above a substrate 203 (e.g., a silicon substrate). Stack structure 201 includes vertically interleaved first dielectric layers 223 and second dielectric layers 225, according to some implementations. First and second dielectric layers 223 and 225 can be alternatingly deposited above substrate 203 to form stack structure 201. In some implementations, each first dielectric layer 223 includes a layer of silicon oxide, and each second dielectric layer 225 includes a layer of silicon nitride. Stack structure 201 can be formed by one or more thin film deposition processes including, but not limited to, chemical vapor deposition (CVD), physical vapor deposition (PVD), atomic layer deposition (ALD), or any combination thereof.

A plurality of channel openings 610 are formed in core array region 101, such that each channel opening 610 becomes the location for growing an individual channel structure 110 as shown in FIG. 6B. Each channel opening 610 extends vertically through stack structure 201 in core array region 101. In some implementations, fabrication processes for forming channel openings 610 include wet etching and/or dry etching, such as deep-ion reactive etching (DRIE). A plurality of dummy channel openings 612, which extend vertically through stack structure 201 can be formed in word line pick-up region 103 simultaneously as channel openings 610 by the same wet etching and/or dry etching, such as DRIE.

As illustrated in FIG. 6B, channel structures 110 can be formed in core array region 101 of stack structure 201. For each channel opening 610, a memory layer (including a blocking layer, a storage layer, and a tunneling layer) and a channel layer are sequentially formed in this order along sidewalls and the bottom surface of the channel opening. In some implementations, the memory layer is first deposited along the sidewalls and bottom surface of the channel opening, and the semiconductor channel is then deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are subsequently deposited to form the memory layer and the channel layer of channel structure 110.

In some implementations, as illustrated in FIG. 6B, dummy channel structures 112 can be formed in word line pick-up region 103 of stack structure 201, in the same process of forming channel structures 110. For example, dummy channel structures 112 can be formed simultaneously as channel structures 110 by the same thin film deposition processes that deposit a memory layer (including a blocking layer, a storage layer, and a tunneling layer) and a channel layer into the dummy channel openings. It is understood that in some examples, dummy channel structures 112 may be formed in a separate process from channel structures 110.

As illustrated in FIG. 6C, a first slit opening 620 extending through first dielectric layers 223 and second dielectric layers 225 and across core array region 101 and word line pick-up region 103 of stack structure 201 is formed. First slit opening 620 can be an opening that extends vertically through first dielectric layers 223 and second dielectric layers 225 of stack structure 201 until substrate 203. First slit opening 620 can also extend laterally across core array region 101 and word line pick-up region 103 in the x-direction (the word line direction), for example, corresponding to slit structure 108 in FIG. 1. In some implementations, fabrication processes for forming first slit opening 620 include wet etching and/or dry etching, such as DRIE, of first dielectric layers 223 and second dielectric layers 225. The etching process through stack structure 201 may not stop at the top surface of substrate 203 and may continue to etch part of substrate 203 to ensure that first slit opening 620 extends vertically all the way through all first dielectric layers 223 and second dielectric layers 225 of stack structure 201.

In FIG. 6D, first slit opening 620 can be filled with a preliminary slit structure 621 (e.g., a sacrificial layer). For example, first slit opening 620 in core array region 101 and word line pick-up region 103 can be covered by the sacrificial layer. In some implementations, the sacrificial layer that is different from first dielectric layers 223 and second dielectric layers 225, such as a polysilicon layer or a carbon layer, is deposited into first slit opening using one or more thin film deposition processes, such as CVD, PVD, ALD, or any combination thereof, to fill first slit opening 620. A chemical mechanical polishing (CMP) process may be performed on the sacrificial layer.

In FIG. 6E, a first dielectric sub-layer 623 may be deposited over stack structure 201 to cover preliminary slit structure 621. First dielectric sub-layer 623 can be formed by one or more thin film deposition processes including, but not limited to, chemical vapor deposition (CVD), physical vapor deposition (PVD), atomic layer deposition (ALD), or any combination thereof. First dielectric sub-layer 623 can include dielectric materials including, but not limited to, silicon oxide, silicon nitride, silicon oxynitride, or any combination thereof.

A first contact opening 622 extending through first dielectric sub-layer 623 and a part of the first portion of stack structure 201 (e.g., in dielectric portion 107 of word line pick-up region 103) can be formed. In some implementations, fabrication processes for forming first contact opening 622 include wet etching and/or dry etching, such as DRIE, of first dielectric sub-layer 623, first dielectric layers 223, and second dielectric layers 225.

In FIG. 6F, a spacer 404 can be formed by depositing a first dielectric material on a sidewall of first contact opening 622. For example, spacer 404 can be formed on the sidewall and the bottom surface of first contact opening 622, thereby covering first dielectric layers 223 and second dielectric layers 225 exposed from the sidewall of first contact opening 622. In some implementations, spacer 404 is formed by depositing dielectric materials, such as silicon oxide, using one or more thin film deposition processes, such as ALD, CVD, PVD, any other suitable processes, or any combination thereof, over the sidewall and the bottom surface of first contact opening 622. A part of spacer 404 on the bottom of first contact opening 622 is removed to expose a part of a first one of second dielectric layers 225 in dielectric portion 107 of word line pick-up region 103. In some implementations, the etching rate, direction, and/or duration of RIE are controlled to etch only the part of spacer 404 on the bottom surface, but not on the sidewall, of first contact opening 622, i.e., “punching” through spacer 404 in the z-direction to expose only the first one of second dielectric layers 225 from the bottom, but not other second dielectric layers 225 from the sidewall.

In FIG. 6G, a lateral recess 625 is formed below the bottom of first contact opening 622 by removing a part of the first one of second dielectric layers 225 exposed at the bottom of first contact opening 622. For example, the part of the first one of second dielectric layers 225 exposed from the bottom of first contact opening 622 is removed by wet etching to form lateral recess 625, leaving the remainder of the first one of second dielectric layers 225 at the same level, as well as other second dielectric layers 225 at other levels, in dielectric portion 107 of word line pick-up region 103 intact. In some implementations, the part of the first one of second dielectric layers 225 is wet etched by applying a wet etchant through first contact opening 622, creating lateral recess 625 sandwiched between two first dielectric layers 223. The wet etchant can include phosphoric acid for etching the first one of second dielectric layers 225 including silicon nitride. In some implementations, the etching rate and/or etching time are controlled to remove only part of the first one of second dielectric layers 225. By controlling the etching time, the wet etchant does not travel all the way to completely remove the first one of second dielectric layers 225 in dielectric portion 107 of word line pick-up region 103. Since the sidewall of first contact opening 622 is still covered by spacer 404 (e.g., silicon oxide) that is resistant to the etchant for removing the part of the first one of second dielectric layers 225 (e.g., silicon nitride), second dielectric layers 225 at other levels remain intact in dielectric portion 107.

In FIG. 6H, first contact opening 622 and lateral recess 625 are filled with a second dielectric material (e.g., a sacrificial layer) different from that of first dielectric layers 223 and second dielectric layers 225. In some implementations, the second dielectric material, such as polysilicon, can be deposited in lateral recess 625 and first contact opening 622 using one or more thin film deposition processes, such as ALD, CVD, PVD, any other suitable processes, or any combination thereof. A CMP process may be performed on the second dielectric material filled in first contact opening 622.

In FIG. 6I, a second dielectric sub-layer 627 is deposited over first dielectric sub-layer 623 to cover the second dielectric material filled in first contact opening 622. Second dielectric sub-layer 627 can be formed by one or more thin film deposition processes including, but not limited to, chemical vapor deposition (CVD), physical vapor deposition (PVD), atomic layer deposition (ALD), or any combination thereof. Second dielectric sub-layer 627 can include dielectric materials including, but not limited to, silicon oxide, silicon nitride, silicon oxynitride, or any combination thereof.

Subsequently, with reference to FIGS. 6J-6L, a gate line replacement process may be performed to replace parts of second dielectric layers 225 in the second portion of stack structure 201 with conductive layers 222. For example, all the second dielectric layers 225 in core array region 101 and parts of second dielectric layers 225 in conductive portion 105 of word line pick-up region 103 are replaced with conductive layers 222, for example, by the gate line replacement process.

In FIG. 6J, a second slit opening 628 can be formed to expose preliminary slit structure 621. Second slit opening 628 can be an opening that extends vertically through first dielectric sub-layers 623 and second dielectric sub-layers 627 to expose the top surface of preliminary slit structure 621. A size of second slit opening 628 may be greater than a size of first slit opening 620 in the y direction. Second slit opening 628 can also extend laterally across core array region 101 and word line pick-up region 103 in the x-direction (the word line direction), for example, corresponding to slit structure 108 in FIG. 1. In some implementations, fabrication processes for forming second slit opening 628 include wet etching and/or dry etching, such as DRIE, of first dielectric sub-layers 623 and second dielectric sub-layers 627.

In FIG. 6K, preliminary slit structure 621 (shown in FIGS. 6D-6J) can be removed to expose first slit opening 620. For example, first slit opening 620 is re-opened by removing the sacrificial layer of preliminary slit structure 621 to expose first dielectric layers 223 and second dielectric layers 225. In some implementations, the sacrificial layer is etched away from first slit opening 620, for example, using potassium hydroxide (KOH) for etching the sacrificial layer having polysilicon, to open first slit opening 620.

Next, the parts of second dielectric layers 225 in the second portion of stack structure 201 are removed through first slit opening 620 to form a plurality of lateral openings 629, 630. The plurality of lateral openings 629 are in core array region 101. The plurality of lateral openings 630 are in conductive portion 105 of word line pick-up region 103.

For example, all second dielectric layers 225 (as shown in FIG. 6J) in core array region 101 are fully removed by wet etching to form lateral openings 629. In some implementations, second dielectric layers 225 are wet etched by applying a wet etchant through first slit opening 620. The wet etchant can include phosphoric acid for etching second dielectric layers 225 including silicon nitride. In some implementations, the etching rate and/or etching time are controlled to ensure that all second dielectric layers 225 in core array region 101 are completely etched away.

Further, parts of second dielectric layers 225 in conductive portion 105 of word line pick-up region 103 are removed by wet etching to form lateral openings 630, leaving the remainders of second dielectric layers 225 in dielectric portion 107 of word line pick-up region 103 intact. By controlling the etching time, the wet etchant does not travel all the way to completely remove second dielectric layers 225 in word line pick-up region 103, thereby defining two portions in word line pick-up region 103—conductive portion 106 in which second dielectric layers 225 are removed, and dielectric portion 107 in which second dielectric layers 225 remain. It is noted that since lateral recess 625 (shown in FIG. 6G) is filled with dielectric material, such as polysilicon, which is resistant to the wet etchant, a size of a lateral opening 630a in the same level as the first one of second dielectric layers 225 can be shorter than that of other lateral openings 630 in other levels of second dielectric layers 225 in the y-direction (e.g., the length of lateral opening 630a in the y-direction <a length of a lateral opening 630b in the y-direction).

In FIG. 6L, high-k gate dielectric layers 220 are formed on walls of the plurality of lateral openings 629, 630. Then, the plurality of lateral openings 629, 630 are filled with a first conductive material to form conductive layers 222 such that end surfaces and side surfaces of conductive layers 222 are surrounded by high-k gate dielectric layers 220, respectively. For example, conductive layers 222 are deposited into lateral recesses 629 and 630 in core array region 101 and conductive portion 105 of word line pick-up region 103 through first slit opening 620 and second slit opening 628. High-k gate dielectric layers 220 are deposited into lateral recesses 629 and 630 prior to conductive layers 222, such that conductive layers 222 are deposited on and surrounded by high-k gate dielectric layers 220. Conductive layers 222, such as metal layers, can be deposited using one or more thin film deposition processes, such as ALD, CVD, PVD, any other suitable processes, or any combination thereof.

In FIG. 6M, slit structure 108 is formed to fill first slit opening 620 and second slit opening 628. A third dielectric sub-layer 631 is deposited over second dielectric sub-layer 627 to cover slit structure 108 formed in first and second slit openings 620, 628. Third dielectric layer 412 of FIG. 4 may include first, second and third dielectric sub-layer 623, 627, 631. With combined reference to FIGS. 5C, 6L, and 6M, first slit segment 540 of slit structure 108 may be formed in second slit opening 628. Second slit segment 542 of slit structure 108 may be formed in first slit opening 620. In one example, second joint region 418 may include a region where first slit segment 540 connects with second slit segment 542. In another example, second joint region 418 may include a region where first slit opening 620 connects with second slit opening 628 in third dielectric layer 412.

In some implementations, first and second slit openings 620 and 628 are formed using a chopping process, respectively, which employs two different masks so that first and second slit openings 620 and 628 can reach different depths inside stack structure 201 and have different opening widths in the y direction. However, sidewall shoulders (such as sidewall shoulders 699 in FIG. 6L) are easy to be created in the openings as a result of multiple times of etching with masks having a gap or overlay therebetween. Slit structure 108 (e.g., first slit segment 540 of slit structure) may have slit shoulders 698 as shown in FIG. 6M. Slit shoulders 698 may rest on sidewall shoulders 699 (shown in FIG. 6L). Second joint region 418 may include a region where sidewall shoulders 699 of FIG. 6L are located, and slit shoulders 698 are formed above second joint region 418.

Stop layer 231 can be formed on core array region 101 of stack structure 201, using one or more thin film deposition processes including, but not limited to, CVD, PVD, ALD, or any combination thereof. DSG channel structures 227 can be formed extending vertically through stop layer 231 to be in contact with the upper ends of channel structures 110. Channel contacts 226 can be formed in stop layer 231.

In FIG. 6N, a second contact opening 634 is formed in third dielectric layer 412 to expose the second dielectric material filled in first contact opening 622. In some implementations, fabrication processes for forming second contact opening 634 include wet etching and/or dry etching, such as DRIE, of third dielectric layer 412.

In FIG. 6O, the second dielectric material filled in lateral recess 625 and first contact opening 622 is removed through second contact opening 634 to expose lateral recess 625 and a sidewall of spacer 404. A size of second contact opening 634 is greater than a size of first contact opening 622 in the y-direction. In some implementations, the second dielectric material is etched away from first contact opening 622 and lateral recess 625, for example, using potassium hydroxide (KOH) to re-open first contact opening 622 and lateral recess 625.

In FIG. 6P, a high-k gate dielectric layer 220a (shown in FIG. 6O) on an end surface 636 of the first one of conductive layers 222 is removed to expose end surface 636 of the first one of conductive layers 222. For example, high-k gate dielectric layer 220a can be etched, for example, using wet etching, to expose end surface 636 of the first one of conductive layers 222.

In FIG. 6Q, a second conductive material is deposited to fill lateral recess 625 to form lateral contact member 406. The second conductive material is also deposited on the sidewall of spacer 404 and on a sidewall of second contact opening 634 to form vertical contact member 402. Lateral contact member 406 and vertical contact member 402 can be deposited using one or more thin film deposition processes, such as ALD, CVD, PVD, any other suitable processes, or any combination thereof. Lateral contact member 406 connects with end surface 636 of the first one of conductive layers 222.

With combined reference to FIGS. 5A, 6O, 6Q, and 6R, first contact segment 502 of contact structure 106 may be formed in second contact opening 634. Second contact segment 504 of contact structure 106 may be formed in first contact opening 622. In one example, first joint region 410 may include a region where first contact segment 502 connects with second contact segment 504. In another example, first joint region 410 may include a region where first contact opening 622 connects with second contact opening 634 in third dielectric layer 412.

In some implementations, first and second contact openings 622 and 634 are formed using a chopping process, respectively, which employs two different masks so that first and second contact openings 622 and 634 can reach different depths inside stack structure 201 and have different opening widths in the y direction. However, sidewall shoulders (such as sidewall shoulders 697 in FIG. 6O) are easy to be created in the openings as a result of multiple times of etching with masks having a gap or overlay therebetween. Contact structure 106 (e.g., first contact segment 502 of contact structure 106) may include contact shoulders 696 as shown in FIG. 6Q. For example, contact shoulders 696 can be a part of vertical contact member 402 and can be in first contact segment 502. Contact shoulders 696 may rest on sidewall shoulders 697 (shown in FIG. 6O). First joint region 410 may include a region where sidewall shoulders 697 of FIG. 6O are located, and contact shoulders 696 are formed above first joint region 410.

In FIG. 6R, a remaining space of first contact opening 622 and a remaining space of second contact opening 634 are filled with a third dielectric material to form filler body 408. A contact pad 650 can be formed on the top surface of filler body 408. For example, the third dielectric material can be deposited using one or more thin film deposition processes, such as ALD, CVD, PVD, any other suitable processes, or any combination thereof, to form filler body 408.

As described above with reference to FIG. 6H, the second dielectric material (such as polysilicon) can be filled in lateral recess 625, so that the first one of second dielectric layers 225 (including silicon nitride) interfaces polysilicon directly. As a result, the removal of the first one of second dielectric layers 225 in conductive portion 105 can be easily controlled to be stopped at the polysilicon interface, as shown in FIG. 6K. After conductive layers 222 are filled in lateral openings 630, polysilicon in lateral recess 625 interfaces high-k gate dielectric layer 222a on end surface 636 of the first one of conductive layers 222, as shown in FIG. 6L (unlike FIG. 3A in which it is silicon nitride that interfaces the high-k gate dielectric layers). As a result, the removal of polysilicon in lateral recess 625 can be easily stopped at high-k gate dielectric layer 220a, as shown in FIG. 6O (e.g., high-k gate dielectric layer 220a is resistant to the wet enchant used to etch the polysilicon). Compared to FIGS. 3B-3C, the etching process in FIG. 6O can be easily controlled, and no damage is made to the high-k gate dielectric layers. That is, the over etching issue of the high-k gate dielectric layers can be avoided. As a result, the manufacture cost of the memory device can be reduced.

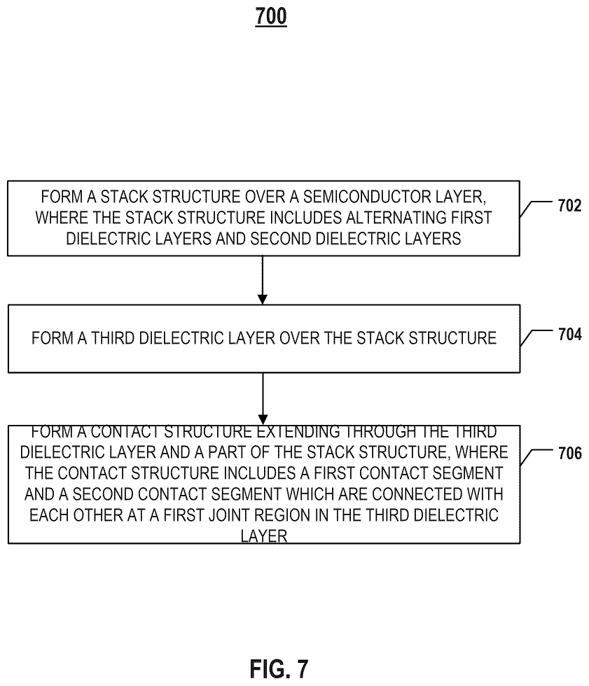

FIG. 7 illustrates a flowchart of a method 700 for forming an example 3D memory device having contact structures, according to some aspects of the present disclosure. Examples of the 3D memory device include 3D memory devices 100 depicted in FIG. 1 or 3D memory device 200 depicted in FIGS. 4, 5A-5C, and 6A-6R. It is understood that the operations shown in method 700 are not exhaustive and that other operations can be performed as well before, after, or between any of the illustrated operations. Further, some of the operations may be performed simultaneously, or in a different order than that shown in FIG. 7.

Referring to FIG. 7, method 700 starts at operation 702, in which a stack structure is formed over a semiconductor layer. The stack structure includes alternating first dielectric layers and second dielectric layers. The semiconductor layer can be, for example, a substrate.

Method 700 proceeds to operation 704, as illustrated in FIG. 7, in which a third dielectric layer is formed over the stack structure.

Method 700 proceeds to operation 706, as illustrated in FIG. 7, in which a contact structure extending through the third dielectric layer and a part of the stack structure is formed. The contact structure includes a first contact segment and a second contact segment which are connected with each other at a first joint region in the third dielectric layer.

Consistent with some aspects of the present disclosure, operations 704 and 706 may be performed together. For example, during the process of forming the contact structure, the third dielectric layer can also be formed, as illustrated above with reference to FIGS. 6E-6R.

In some implementations, with reference to FIGS. 6C-6D and 7, prior to forming the contact structure, method 700 may include forming a first slit opening 620 extending through the stack structure and a part of the semiconductor layer, and filling first slit opening 620 with a preliminary slit structure 621. Then, forming third dielectric layer 412 at operation 704 may include depositing a first dielectric sub-layer 623 over the stack structure to cover preliminary slit structure 621, as illustrated in FIG. 6E. Third dielectric layer 412 may include first dielectric sub-layer 623.

In some implementations, to form the contact structure at operation 706, method 700 may include forming a first contact opening 622 extending through first dielectric sub-layer 623 and a part of a first portion of the stack structure, as illustrated in FIG. 6E. Method 700 may also include forming a spacer 404 by depositing a first dielectric material on a sidewall of first contact opening 622, as illustrated in FIG. 6F. Method 700 may also include forming a lateral recess 625 below a bottom of first contact opening 622 by removing a part of a first one of the second dielectric layers 225 exposed at the bottom of first contact opening 622, as illustrated in FIG. 6G. Method 700 may also include filling first contact opening 622 and lateral recess 625 with a second dielectric material different from that of the first dielectric layers and the second dielectric layers, as illustrated in FIG. 6H.

In some implementations, to form the third dielectric layer at operation 704, method 700 may also include depositing a second dielectric sub-layer 627 over first dielectric sub-layer 623 to cover the second dielectric material filled in the first contact opening, as illustrated in FIG. 6I. The third dielectric layer further includes second dielectric sub-layer 627.

In some implementations, method 700 may further include performing a gate line replacement process to replace parts of the second dielectric layers in a second portion of the stack structure with conductive layers. For example, method 700 may include forming a second slit opening 628 to expose preliminary slit structure 621, as illustrated in FIG. 6J. Method 700 may also include (a) removing preliminary slit structure 621 to expose first slit opening 620 through second slit opening 628 and (b) removing the parts of the second dielectric layers in the second portion of the stack structure through first slit opening 620 to form a plurality of lateral openings, 629, 930, as illustrated in FIG. 6K. Method 700 may also include (a) forming high-k gate dielectric layers 220 on walls of the plurality of lateral openings 629, 630, and (b) filling the plurality of lateral openings 629, 630 with a first conductive material to form conductive layers 222, such that end surfaces and side surfaces of conductive layers 222 are surrounded by high-k gate dielectric layers 220, respectively, as illustrated in FIG. 6L. Method 700 may also include forming a slit structure 108 to fill first slit opening 620 and second slit opening 628, as illustrated in FIG. 6M.

In some implementations, to form the third dielectric layer at operation 704, method 700 may further include depositing a third dielectric sub-layer 631 over second dielectric sub-layer 627 to cover slit structure 108 formed in the first and second slit openings, as illustrated in FIG. 6M. The third dielectric layer may further include third dielectric sub-layer 631.

In some implementations, to form the contact structure at operation 706, method 700 may also include forming a second contact opening 634 in the third dielectric layer 412 to expose the second dielectric material filled in first contact opening 622, as illustrated in FIG. 6N. A size of second contact opening 634 is greater than a size of first contact opening 622 in the y-direction. Method 700 may also include removing the second dielectric material through second contact opening 634 to expose lateral recess 625 and a sidewall of spacer 404, as illustrated in FIG. 6O. Method 700 may further include removing the first corresponding high-k gate dielectric layer 220a on end surface 636 of the first one of the conductive layers to expose the end surface 636 of the first one of the conductive layers, as illustrated in FIG. 6P. Method 700 may further include (a) depositing a second conductive material to fill lateral recess 625 to form a lateral contact member 406 and (b) depositing the second conductive material on the sidewall of spacer 404 and on a sidewall of second contact opening 634 to form a vertical contact member 402, as illustrated in FIG. 6Q. Method 700 may further include filling a remaining space of first contact opening 622 and a remaining space of second contact opening 634 with a third dielectric material to form a filler body 408, as illustrated in FIG. 6R.

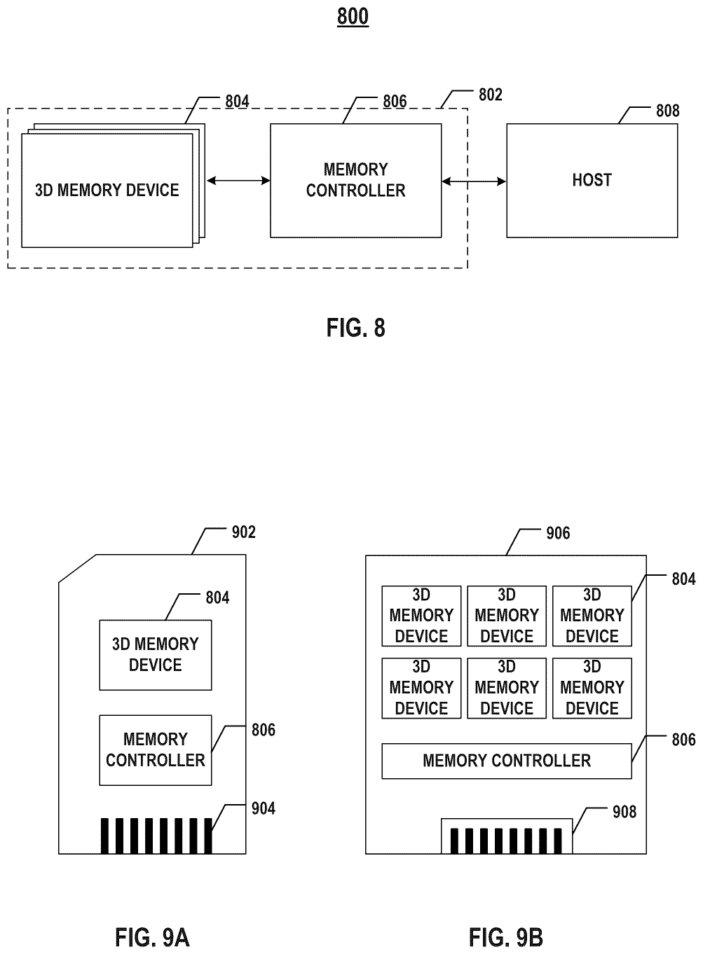

FIG. 8 illustrates a block diagram of an example system 800 having a 3D memory device, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more 3D memory devices 804 and a memory controller 806. Host 808 can be a processor of an electronic device, such as a central processing unit (CPU), or a system-on-chip (SoC), such as an application processor (AP). Host 808 can be configured to send or receive data to or from 3D memory devices 804.

3D memory device 804 can be any 3D memory device disclosed herein, such as 3D memory device 100 depicted in FIGS. 1 and 3D memory device 400 depicted in FIGS. 4, 5A-5C, and 6A-6R.

Memory controller 806 (a.k.a., a controller circuit) is coupled to 3D memory device 804 and host 808 and is configured to control 3D memory device 804, according to some implementations. For example, memory controller 806 may be configured to operate the plurality of channel structures via the word lines. Memory controller 806 can manage the data stored in 3D memory device 804 and communicate with host 808. In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804. Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 9A, memory controller 806 and a single 3D memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 electrically coupling memory card 902 with a host (e.g., host 808 in FIG. 8). In another example as shown in FIG. 9B, memory controller 806 and multiple 3D memory devices 804 may be integrated into an SSD 906. SSD 906 can further include an SSD connector 908 electrically coupling SSD 906 with a host (e.g., host 808 in FIG. 8). In some implementations, the storage capacity and/or the operation speed of SSD 906 is greater than those of memory card 902.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents.

What is claimed is:

1. A memory device, comprising:
a semiconductor layer;
a stack structure over the semiconductor layer and comprising alternating first layers and first dielectric layers, wherein the first layers in a first portion of the stack structure comprise second dielectric layers, and the first layers in a second portion adjacent to the first portion of the stack structure comprise conductive layers;
a third dielectric layer over the stack structure; and
a contact structure extending through the third dielectric layer and a part of the first portion of the stack structure to be connected with a first one of the conductive layers, wherein the contact structure comprises a first contact segment and a second contact segment which are connected with each other at a first joint region in the third dielectric layer.

2. The memory device of claim 1, wherein:
the first contact segment extends through a first part of the third dielectric layer in a first direction;
the second contact segment extends through a second part of the third dielectric layer and the part of the stack structure in the first direction; and
a size of the first contact segment is greater than a size of the second contact segment in a second direction perpendicular to the first direction.

3. The memory device of claim 1, wherein:
the contact structure comprises a vertical contact member extending in a first direction and a lateral contact member connecting to the vertical contact member and extending in a second direction;
the lateral contact member connects with the first one of the conductive layers;
the first contact segment comprises a first part of the vertical contact member;
the second contact segment comprises a second part of the vertical contact member; and
the first part and the second part of the vertical contact member connect with each other at the first joint region in the third dielectric layer.

4. The memory device of claim 3, wherein:
the second dielectric layers in the first portion of the stack structure comprise:
a first one of the second dielectric layers at a same level as the first one of the conductive layers; and
a second one of the second dielectric layers at a same level as a second one of the conductive layers;
an end surface of the second one of the conductive layers is covered by a first high dielectric constant (high-k) gate dielectric layer, and the second one of the conductive layers connects with the second one of the second dielectric layers via the first high-k gate dielectric layer; and
the lateral contact member of the contact structure protrudes into the second portion of the stack structure and connects with the first one of the conductive layers.

5. The memory device of claim 4, wherein:
side surfaces of the first one of the conductive layers are surrounded by second high-k gate dielectric layers; and
side surfaces of the second one of the conductive layers are surrounded by third high-k gate dielectric layers.

6. The memory device of claim 3, wherein the lateral contact member and the first one of the conductive layers comprise Titanium nitride and tungsten, respectively.

7. The memory device of claim 4, further comprising:
a slit structure comprising a first slit segment and a second slit segment,
wherein the first slit segment extends through a third part of the third dielectric layer,
wherein the second slit segment extends through a fourth part of the third dielectric layer, the first portion of the stack structure, and a part of the semiconductor layer,
wherein the first slit segment connects with the second slit segment at a second joint region in the third dielectric layer,
wherein a first distance from the slit structure to an end surface of the first one of the conductive layers in the second direction is smaller than a second distance from the slit structure to the end surface of the second one of the conductive layers in the second direction, and
wherein a size of the first slit segment is greater than a size of the second slit segment in the second direction.

8. A method for forming a memory device, comprising:
forming a stack structure over a semiconductor layer, wherein the stack structure comprises alternating first dielectric layers and second dielectric layers;
forming a third dielectric layer over the stack structure; and
forming a contact structure extending through the third dielectric layer and a part of the stack structure, wherein the contact structure comprises a first contact segment and a second contact segment which are connected with each other at a first joint region in the third dielectric layer.

9. The method of claim 8, wherein forming the contact structure comprises:
forming a spacer;
forming a vertical contact member extending in a first direction and a lateral contact member extending in a second direction perpendicular to the first direction, wherein the vertical contact member connects with the lateral contact member, and at least a part of the vertical contact member is surrounded by the spacer; and
forming a filler body, wherein the filler body is surrounded by the vertical contact member.

10. The method of claim 9, wherein prior to forming the contact structure, the method further comprises:
forming a first slit opening extending through the stack structure and a part of the semiconductor layer; and
filling the first slit opening with a preliminary slit structure,
wherein forming the third dielectric layer comprises depositing a first dielectric sub-layer over the stack structure to cover the preliminary slit structure,
wherein the third dielectric layer comprises the first dielectric sub-layer,
wherein forming the contact structure further comprises forming a first contact opening extending through the first dielectric sub-layer and the part of the stack structure, and
wherein forming the spacer comprises depositing a first dielectric material on a sidewall of the first contact opening.

11. The method of claim 10, wherein forming the vertical contact member and the lateral contact member comprises:
forming a lateral recess below a bottom of the first contact opening by removing a part of a first one of the second dielectric layers exposed at the bottom of the first contact opening; and
filling the first contact opening and the lateral recess with a second dielectric material different from that of the first dielectric layers and the second dielectric layers,
wherein forming the third dielectric layer further comprises:
depositing a second dielectric sub-layer over the first dielectric sub-layer to cover the second dielectric material filled in the first contact opening, wherein the third dielectric layer further comprises the second dielectric sub-layer.

12. The method of claim 11, wherein:
the stack structure comprises a first portion and a second portion adjacent to the first portion, and the contact structure extends through the third dielectric layer and a part of the first portion of the stack structure; and
the method further comprises:
performing a gate line replacement process to replace parts of the second dielectric layers in the second portion of the stack structure with conductive layers.

13. The method of claim 12, wherein performing the gate line replacement process comprises:
forming a second slit opening to expose the preliminary slit structure;
removing the preliminary slit structure to expose the first slit opening through the second slit opening;
removing the parts of the second dielectric layers in the second portion of the stack structure through the first slit opening to form a plurality of lateral openings;
forming high dielectric constant (high-k) gate dielectric layers on walls of the plurality of lateral openings, and filling the plurality of lateral openings with a first conductive material to form the conductive layers such that end surfaces and side surfaces of the conductive layers are surrounded by the high-k gate dielectric layers, respectively; and
forming a slit structure to fill the first slit opening and the second slit opening.

14. The method of claim 13, wherein:
the lateral recess filled with the first dielectric material protrudes into the second portion of the stack structure and connects with a first corresponding high-k gate dielectric layer on an end surface of a first one of the conductive layers;
a second one of the second dielectric layers in the first portion of the stack structure connects with a second corresponding high-k gate dielectric layer at an end surface of a second one of the conductive layers; and
forming the third dielectric layer further comprises depositing a third dielectric sub-layer over the second dielectric sub-layer to cover the slit structure formed in the first and second slit openings, wherein the third dielectric layer further comprises the third dielectric sub-layer.

15. The method of claim 14, wherein forming the vertical contact member and the lateral contact member further comprises:
forming a second contact opening in the third dielectric layer to expose the second dielectric material filled in the first contact opening, wherein a size of the second contact opening is greater than a size of the first contact opening in the second direction;
removing the second dielectric material through the second contact opening to expose the lateral recess and a sidewall of the spacer;
removing the first corresponding high-k gate dielectric layer on the end surface of the first one of the conductive layers to expose the end surface of the first one of the conductive layers; and
depositing a second conductive material to fill the lateral recess, on the sidewall of the spacer, and on a sidewall of the second contact opening to form the lateral contact member and the vertical contact member, respectively.

16. The method of claim 15, wherein:
the lateral contact member of the contact structure protrudes into the second portion of the stack structure and connects with the first one of the conductive layers; and
the first joint region comprises a region where the first contact opening connects with the second contact opening in the third dielectric layer.

17. The method of claim 15, wherein forming the filler body comprises:
filling a remaining space of the first contact opening and a remaining space of the second contact opening with a third dielectric material.

18. The method of claim 14, wherein:
the slit structure comprises a first slit segment filling the first slit opening and a second slit segment filling the second slit opening;
the first slit segment connects with the second slit segment at a second joint region in the third dielectric layer;
a size of the first slit segment is greater than a size of the second slit segment in the second direction; and
a first distance from the slit structure to the end surface of the first one of the conductive layers in the second direction is smaller than a second distance from the slit structure to the end surface of the second one of the conductive layers in the second direction.

19. The method of claim 9, wherein:
the first contact segment comprises a first part of the vertical contact member and a first part of the filler body;
the second contact segment comprises a second part of the vertical contact member and a second part of the filler body;
the first part and the second part of the vertical contact member connect with each other at the first joint region in the third dielectric layer;
the first part and the second part of the filler body connect with each other at the first joint region in the third dielectric layer; and
a size of the first contact segment is greater than a size of the second contact segment in the second direction perpendicular to the first direction.

20. A system, comprising:
a memory device, comprising:
a semiconductor layer;
a stack structure over the semiconductor layer and comprising alternating first layers and first dielectric layers, wherein the first layers in a first portion of the stack structure comprise second dielectric layers, and the first layers in a second portion adjacent to the first portion of the stack structure comprise conductive layers;
a third dielectric layer over the stack structure; and
a contact structure extending through the third dielectric layer and a part of the first portion of the stack structure to be connected with a first one of the conductive layers, wherein the contact structure comprises a first contact segment and a second contact segment that are connected with each other at a first joint region in the third dielectric layer; and
a memory controller coupled to the memory device and configured to control an operation of the memory device.
